(19) United States
(12) Patent Application Publication
(10) Pub. No.: US 2020/0393549 A1
(43) Pub. Date: Dec. 17, 2020

(54) DEPTH SENSOR COMPRISING HYBRID PIXEL

(71) Applicant: Samsung Electronics, Co., Ltd., Suwon-si (KR)

(72) Inventors: Younggu JIN, Suwon-si (KR); Youngchan Kim, Seongnam-si (KR); Moosup LIM, Yongin-si (KR); Yonghun KWON, Hwaseong-si (KR)

(73) Assignee: Samsung Electronics Co., Ltd., Suwon-si (KR)

(21) Appl. No.: 16/742,246

(22) Filed: Jan. 14, 2020

(30) Foreign Application Priority Data
Jun. 13, 2019 (KR) 10-2019-0070043

(51) Int. Cl. G01S 7/4863; H04N 5/3745; G01S 17/08; H01L 27/144; H04N 5/378; H01L 31/112

(52) U.S. Cl. CPC G01S 7/4863; H04N 5/37452; H01L 31/1126; H01L 27/1443; H04N 5/378; G01S 17/08

(57) ABSTRACT

Disclosed is a depth sensor that includes a pixel. The pixel includes a photo transistor, a first transfer transistor connected to the photo transistor, a first floating diffusion area connected to the first transfer transistor, a second transfer transistor connected to the photo transistor, a storage element connected to the second transfer transistor, a third transfer transistor connected to the storage element, and a second floating diffusion area connected to the third transfer transistor.

### CROSS-REFERENCE TO RELATED APPLICATIONS

This application claims priority under 35 U.S.C. § 119 to Korean Patent Application No. 10-2019-0070043 filed on Jun. 13, 2019, in the Korean Intellectual Property Office, the contents of which are incorporated by reference herein in their entireties.

### BACKGROUND

Example embodiments of inventive concepts described herein relate to a depth sensor including a hybrid pixel.

An electronic device includes sensors performing various functions, such as calculating a distance between an image sensor and an object by using a captured image and recognizing an object. The electronic device also includes an image sensor that captures an external image for displaying the external image simply. Various electronic devices including a smartphone include depth sensors.

A light signal may be emitted from a light source to an object, and the light signal may be reflected from the object. A depth sensor that is based on a time of flight (ToF) may calculate a distance between the depth sensor and the object based on the reflected light signal. The ambient environment (e.g., a low-illuminance environment or a high-illuminance environment) of the depth sensor may have an influence on calculating the distance of the object. There is required a technology for calculating a distance accurately, to be less dependent on the ambient environment of the depth sensor.

### SUMMARY

Example embodiments of inventive concepts provide a depth sensor including a hybrid pixel.

According to some example embodiments, a depth sensor includes a pixel. The pixel includes a photo transistor, a first transfer transistor connected to the photo transistor, a first floating diffusion area connected to the first transfer transistor, a second transfer transistor connected to the photo transistor, a storage element connected to the second transfer transistor, a third transfer transistor connected to the storage element, and a second floating diffusion area connected to the third transfer transistor.

According to some example embodiments, a depth sensor includes a pixel. The pixel includes a first photo transistor, a first transfer transistor connected to the first photo transistor, a first floating diffusion area connected to the first transfer transistor, a second transfer transistor connected to the first photo transistor, a first storage element connected to the second transfer transistor, a third transfer transistor connected to the first storage element, a second floating diffusion area connected to the third transfer transistor, a second photo transistor, a fourth transfer transistor connected to the second photo transistor, a third floating diffusion area connected to the fourth transfer transistor, a fifth transfer transistor connected to the second photo transistor, a second storage element connected to the fifth transfer transistor, a sixth transfer transistor connected to the second storage element, and a fourth floating diffusion area connected to the sixth transfer transistor.

According to some example embodiments, a depth sensor includes a pixel. The pixel includes a first photo transistor, a first transfer transistor connected to the first photo transistor, a first floating diffusion area connected to the first transfer transistor, a second photo transistor, a second transfer transistor connected to the second photo transistor, a first storage element connected to the second transfer transistor, a third transfer transistor connected to the first storage element, and a second floating diffusion area connected to the third transfer transistor.

### BRIEF DESCRIPTION OF THE FIGURES

The above and other objects and features of inventive concepts will become apparent by describing in detail example embodiments thereof with reference to the accompanying drawings.

FIG. 1 illustrates a block diagram of an electronic device according to some example embodiments of inventive concepts.

FIGS. 2A and 2B illustrate circuit diagrams of a pixel of FIG. 1.

FIGS. 3A to 3R illustrate circuit diagrams of a pixel of FIG. 1.

FIGS. 4A to 4J illustrate layouts of a pixel of FIG. 1.

FIGS. 5A and 5B illustrate timing diagrams of a pixel of FIG. 1.

FIGS. 6A to 6H illustrate circuit diagrams of a pixel of FIG. 1.

FIGS. 7A to 7G illustrate layouts of a pixel of FIG. 1.

FIGS. 8A to 8C illustrate timing diagrams of a pixel of FIG. 1.

### DETAILED DESCRIPTION OF EXAMPLE EMBODIMENTS

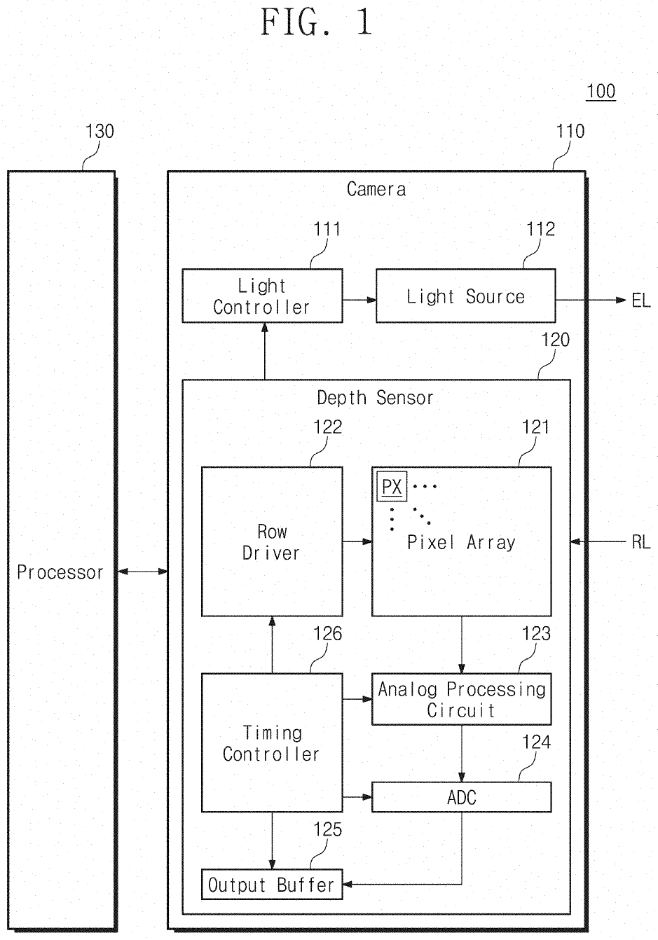

FIG. 1 illustrates a block diagram of an electronic device according to some example embodiments of inventive concepts. An electronic device 100 may be also referred to as a “computing system”, an “electronic system”, an “image detecting system”, or a “distance detecting system”. For example, the electronic device 100 may be or may include a smartphone, a tablet, a digital camera, a wearable device, or a mobile device. The electronic device 100 may include a camera 110 and a processor 130.

The camera 110 may emit a light signal EL to an object based on a time of flight (ToF) technology, may sense a light signal RL reflected from the object, and may sense a distance between the electronic device 100 and the object. The camera 110 may include a light controller 111, a light source 112, and a depth sensor 120.

The light controller 111 may control the light source 112 under control of the depth sensor 120 and/or the processor 130. The light controller 111 may modulate the light signal EL to be emitted/output from the light source 112. The light source 112 may emit the light signal EL modulated by the light controller 111. For example, the modulated light signal EL may have the shape of a square wave (a pulse) and/or a sine wave, and the light signal EL may be an infrared wave, a microwave, a (visible) light wave, or an ultraviolet wave. For example, the light source 112 may include a light emitting diode (LED), a laser diode (LD), and/or an organic light emitting diode (OLED).

The depth sensor 120 may be also referred to as an “image sensor” or a “ToF sensor”. The depth sensor 120 may include a pixel array 121, a row driver 122, an analog processing circuit 123, an analog-to-digital converter 124, an output buffer 125, and a timing controller 126.

The pixel array 121 may include pixels PX arranged along a row direction and a column direction. The pixel array 121 may be implemented on a semiconductor substrate such as a silicon substrate, a silicon-germanium substrate, a silicon-on-insulator (SOI) substrate, etc.; however, inventive concepts are not limited thereto. The pixels PX may convert the light signal RL reflected from an object into an electrical signal. Due to a distance between the electronic device 100 and the object, the light signal incident onto the pixel array 121 may be delayed with respect to the light signal output from the light source 112. There may be a time difference between the light signals RL and EL. The pixel PX may integrate, store, transfer, and/or remove charges based on control signals provided from the row driver 122. The pixel PX may be also referred to as a “ToF pixel”.

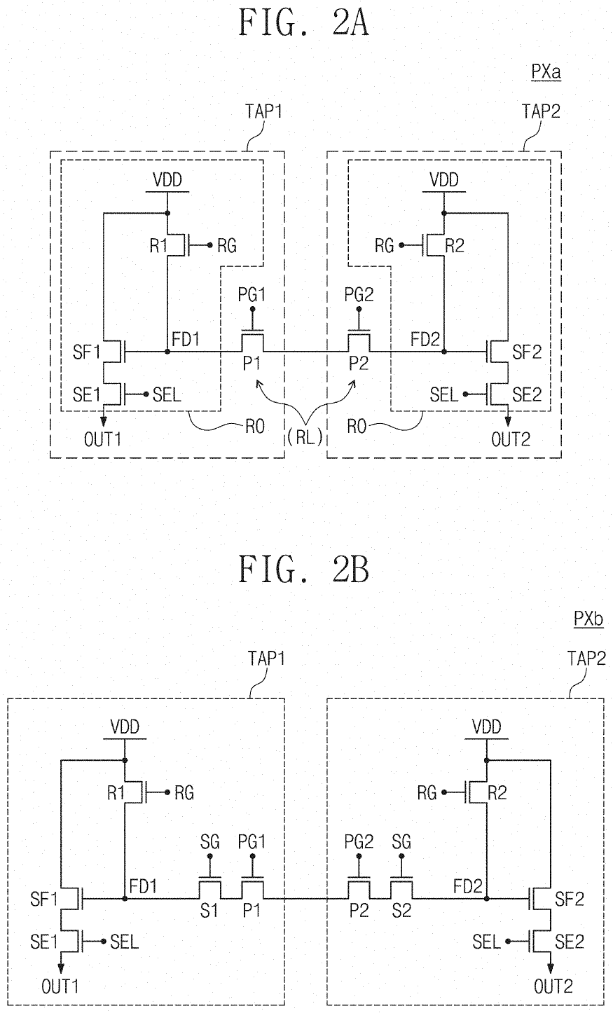

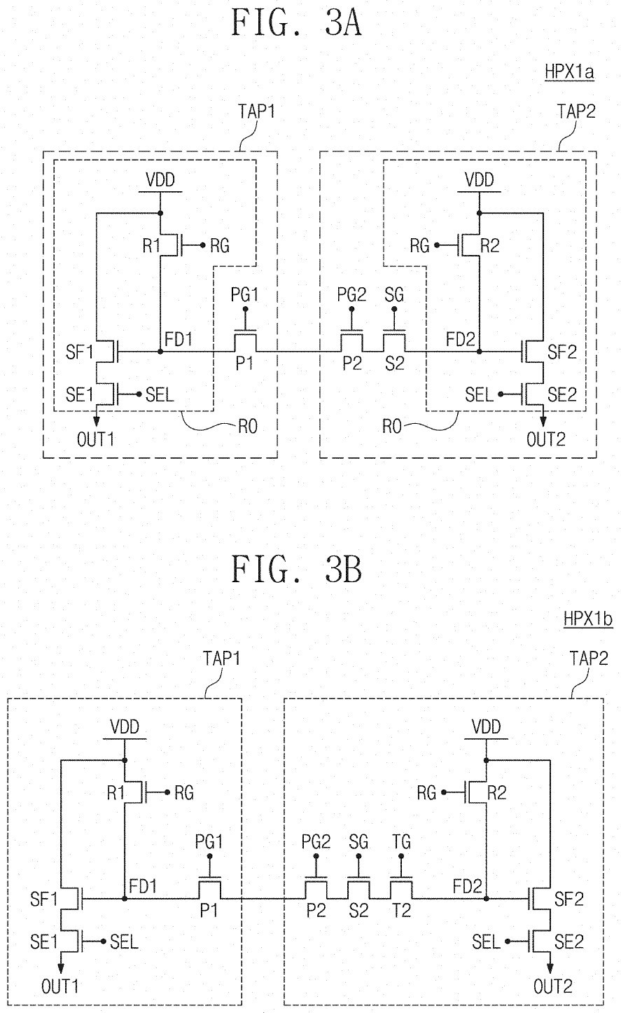

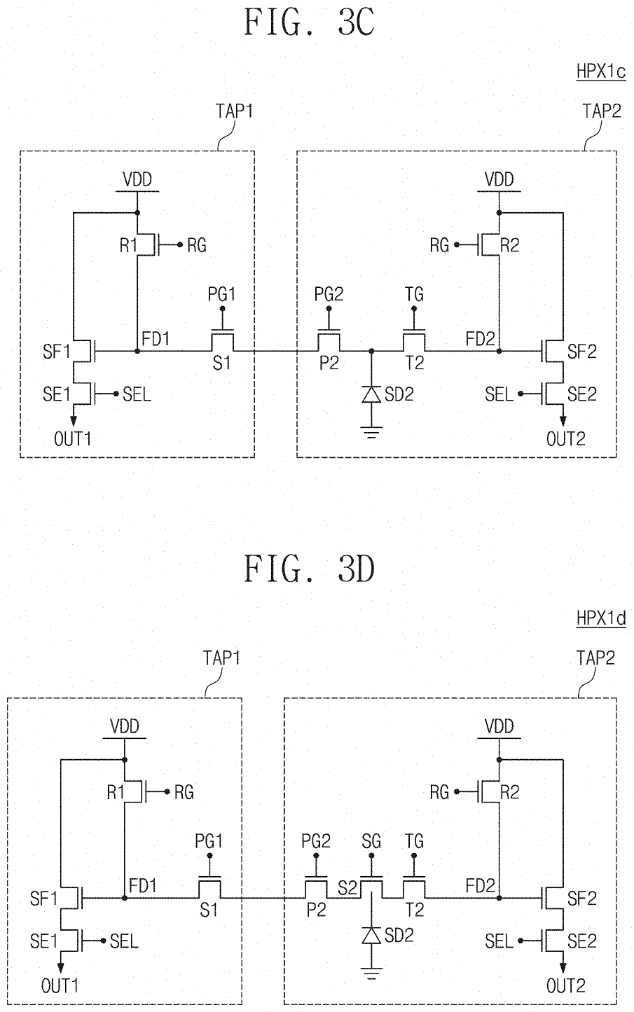

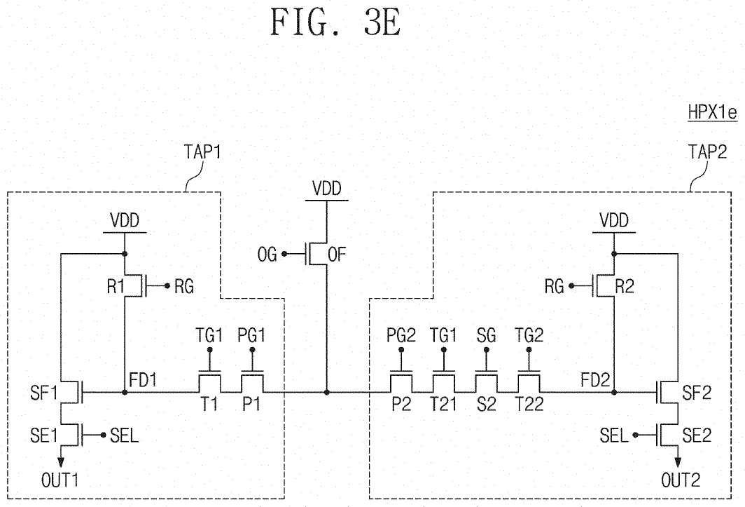

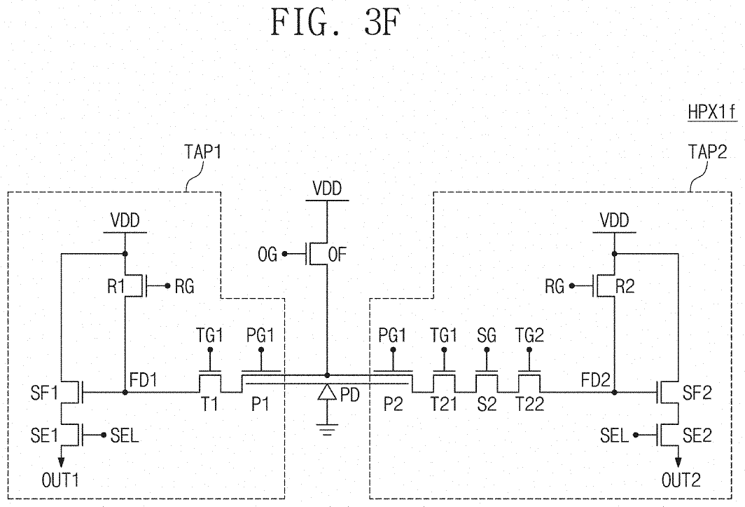

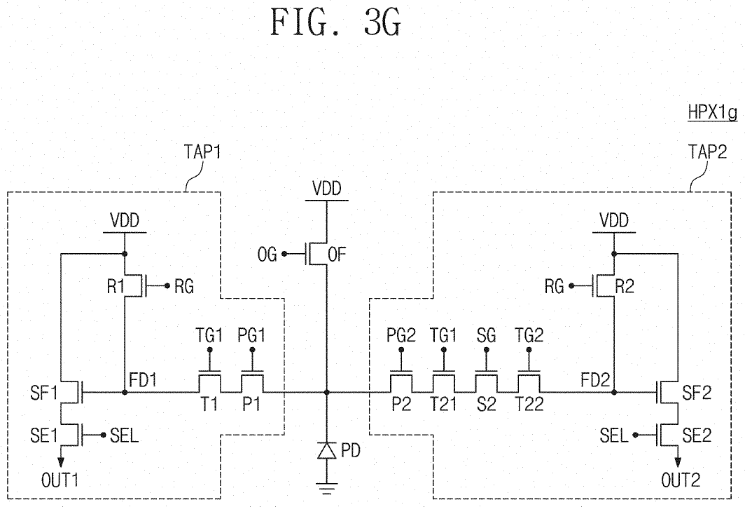

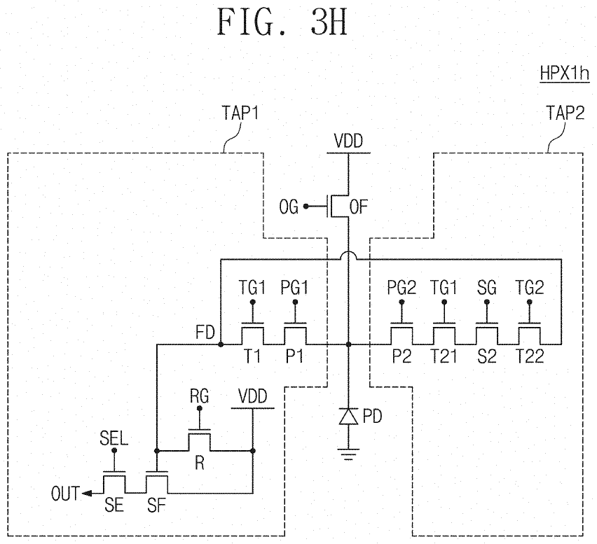

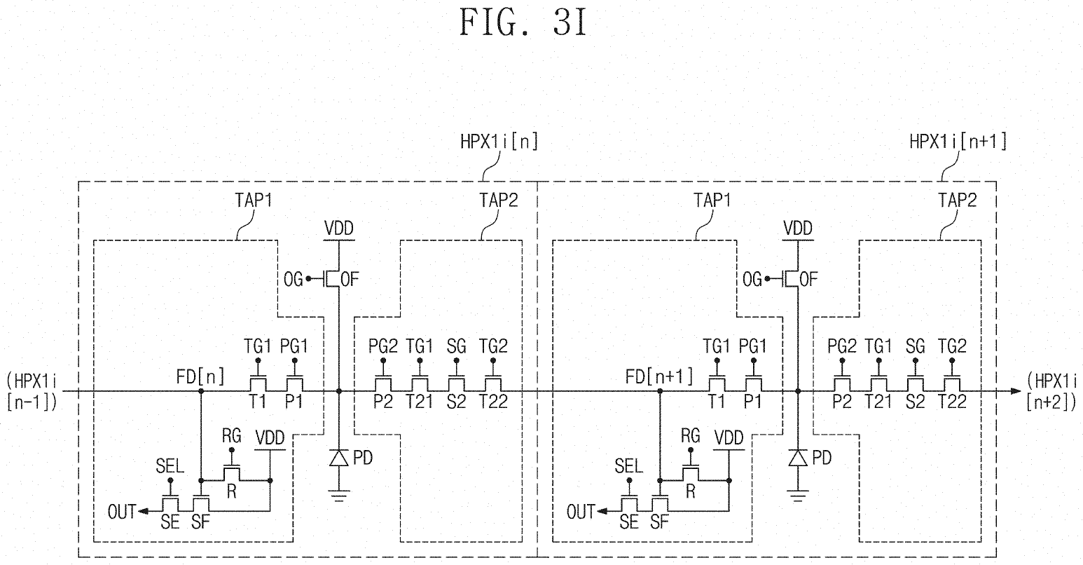

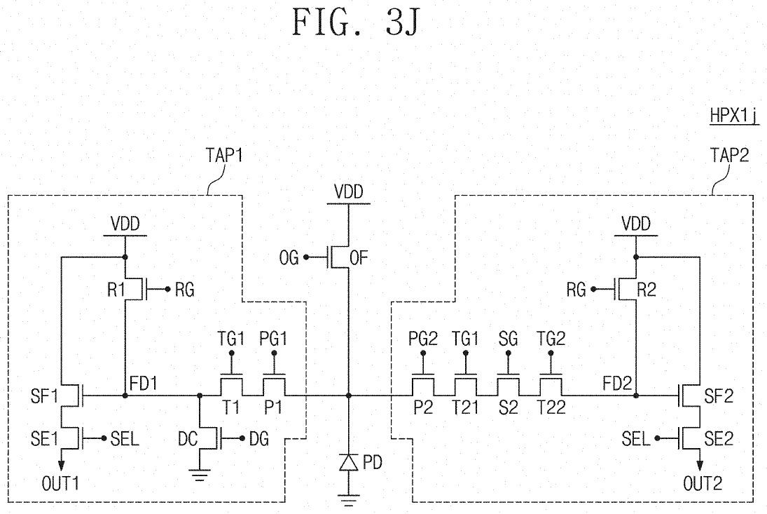

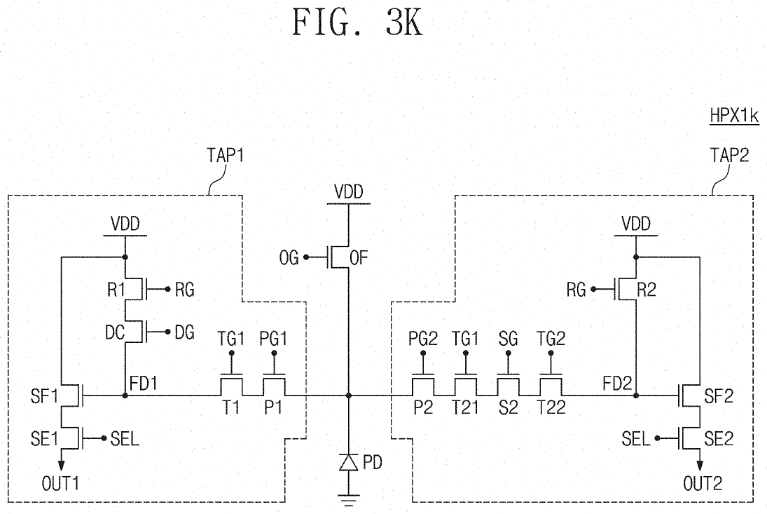

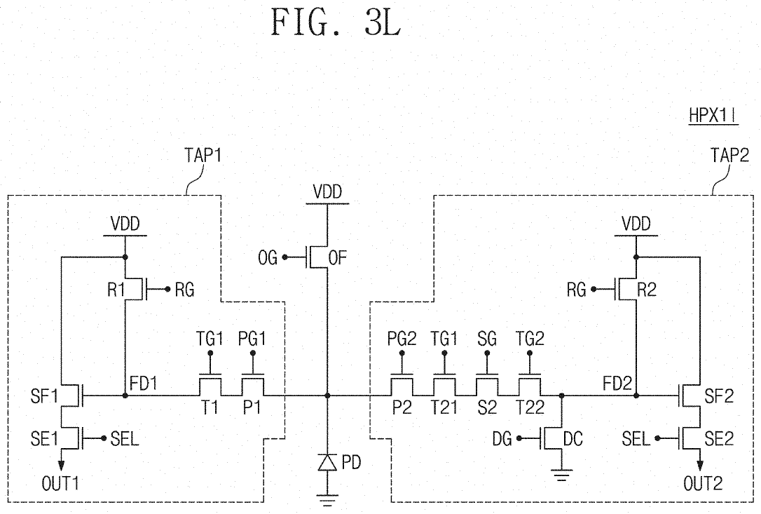

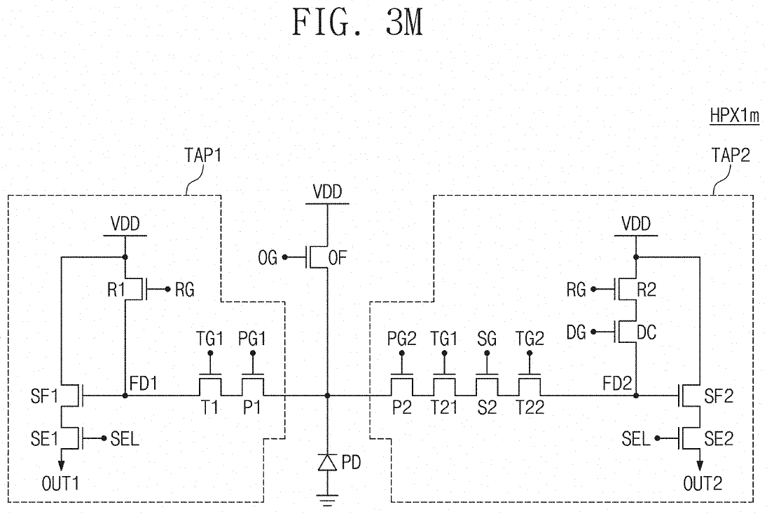

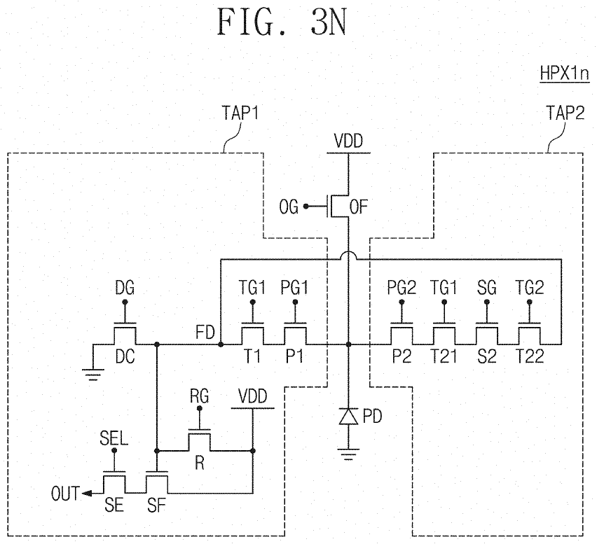

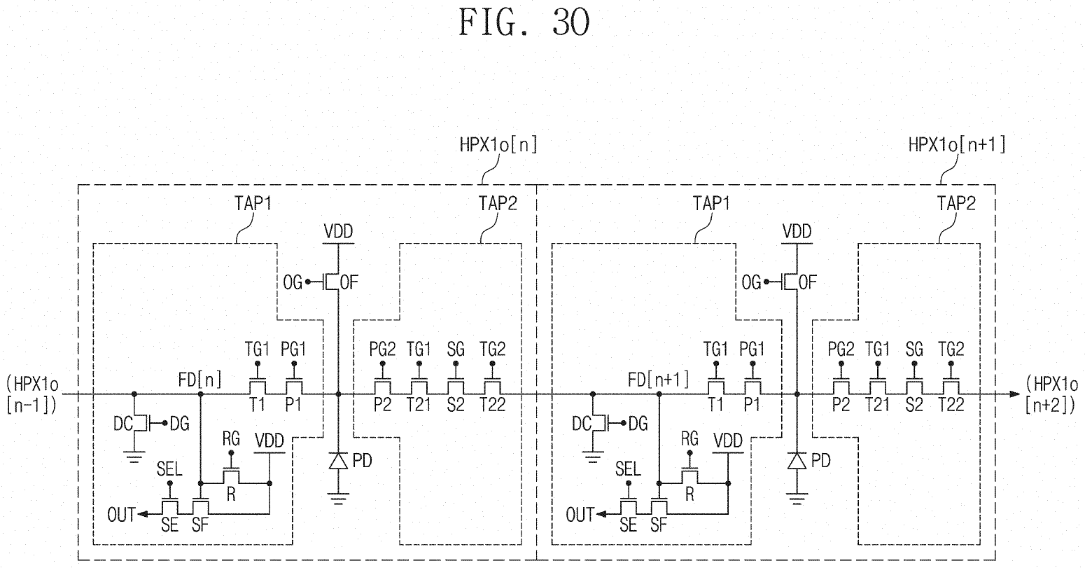

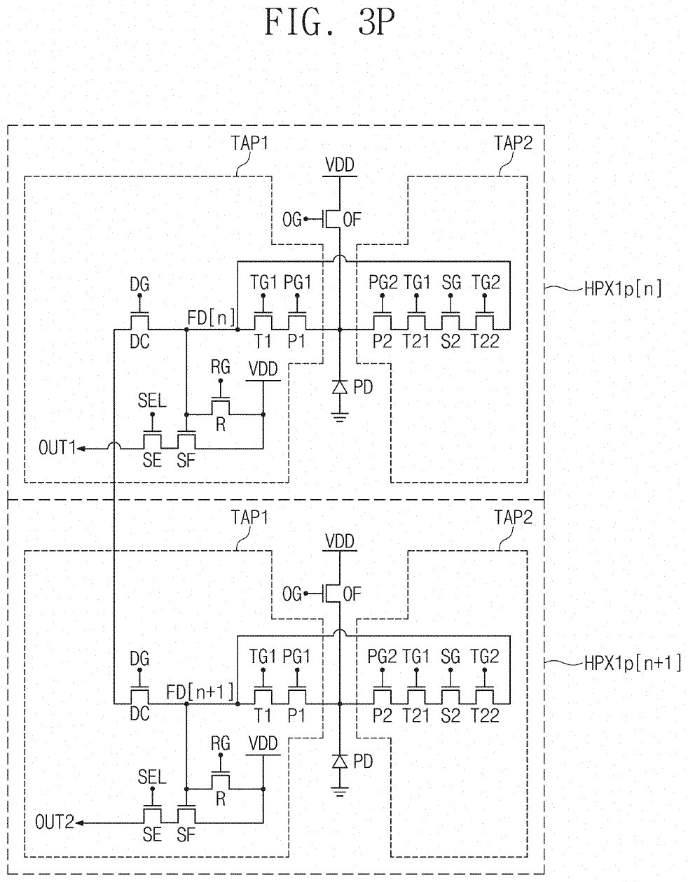

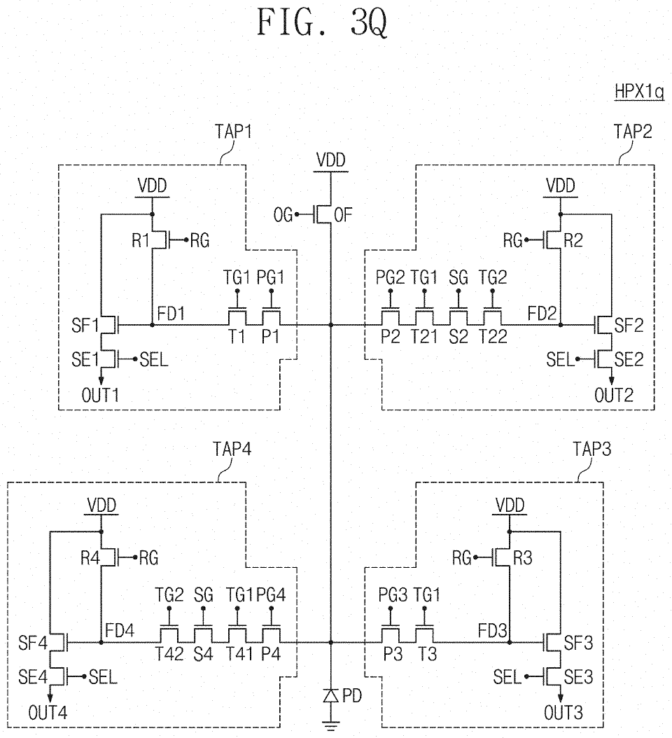

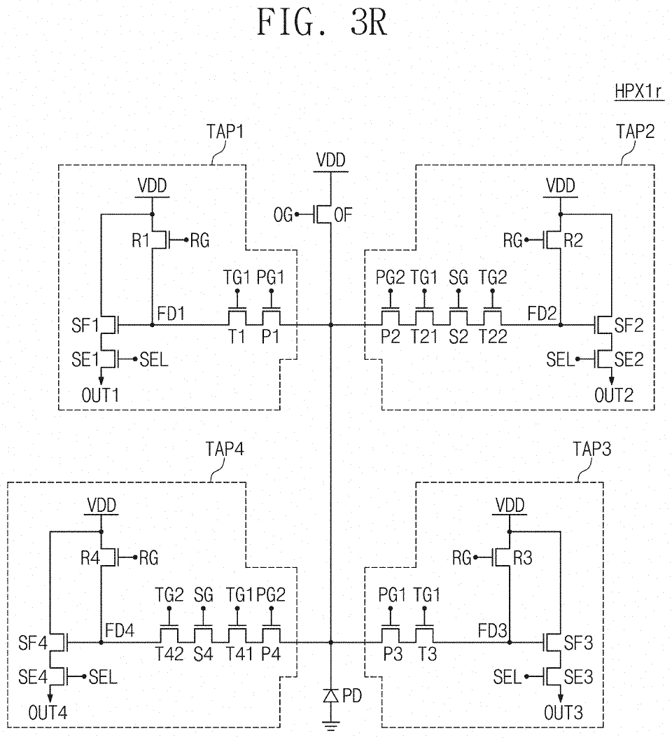

The row driver 122 may control the pixel array 121 under control of the timing controller 126. The row driver 122 may transfer control signals to the pixels PX. For example, the control signals may be OG, PG, TG, SG, RG, SEL, and DG (numerals skipped) illustrated in FIGS. 2A, 2B, 3A to 3R, or 6A to 6H. The row driver 122 may control all of the pixels PX of the pixel array 121 at the same time in a global mode, may control the pixels PX of the pixel array 121 in units of a row in a rolling mode (e.g. a rolling shutter mode), or may control the pixels PX in another mode such as a raster mode; inventive concepts are not limited thereto.

The analog processing circuit 123 may receive, sample, and hold an output signal (also referred to as an “image signal” or a “depth signal”) output from the pixel array 121. The analog processing circuit 123 may be connected to the pixels PX of the pixel array 121 and may control output lines extending in the column direction. The analog processing circuit 123 may perform a correlated double sampling (CDS) operation on the output signal and may remove a noise included in the output signal.

The analog-to-digital converter 124 may convert the output signal processed by the analog processing circuit 123 into a digital signal. The analog-to-digital converter 124 may organize image data and/or depth data by using the digital signal. The analog-to-digital converter 124 may provide the image data to the output buffer 125. For example, the analog-to-digital converter 124 may be included or integrated in the analog processing circuit 123. The output buffer 125 may store the image data transmitted from the analog-to-digital converter 124. The output buffer 125 may output the image data to the processor 130.

The timing controller 126 may control the components 121 to 125 of the depth sensor 120. The timing controller 126 may control the light controller 111 under control of the processor 130. For example, the timing controller 126 may control the row driver 122 based on modulation information and/or phase information of the light signal EL to be output from the light source 112. The row driver 122 may transmit, to the pixel PX, a first modulation signal PG, the phase of which is the same as or different from a phase of the light signal EL, and a second modulation signal PG, the phase of which is different from the phase of the first modulation signal PG, under control of the timing controller 126. The depth sensor 120 may generate first image data by using the first modulation signal PG, may generate second image data by using the second modulation signal PG, and may transmit the first and second image data to the processor 130. The number of modulation signals may be 2 or more.

The processor 130 may control the camera 110. The processor 130 may control the light controller 111 and the light source 112 so as to output the light signal EL. The processor 130 may control the depth sensor 120 so that the depth sensor 120 senses the light signal RL and generates the first and second image data. The processor 130 may calculate a distance (e.g., a ToF value) between the electronic device 100 and an object, a shape of the object, a movement speed of the object, and/or other information, based on the first and second image data. For example, the processor 130 may calculate a delay time of the light signal RL with respect to the light signal EL based on image data that the depth sensor 120 generates by using two or more modulation signals, the phases of which are the same as or different from a phase of the light signal EL. The processor 130 may include an image signal processor (ISP) (not illustrated) for processing image data transmitted from the depth sensor 120. The processor 130 may be also referred to as a “host” and/or a “camera controller”. For example, the processor 130 may be implemented to be independent of the camera 110 as illustrated in FIG. 1. Alternatively, the processor 130 may be integrated in the camera 110 and/or the depth sensor 120.

FIG. 2A illustrates a circuit diagram of a pixel of FIG. 1. A pixel PXa may include taps TAP1 and TAP2. The tap TAP1 may include a photo transistor P1 and a readout circuit RO. The readout circuit RO may include a floating diffusion area FD1, a reset transistor R1, a source follower transistor SF1, and a selection transistor SE1.

One end (e.g. a drain or a source) of the photo transistor P1 may be connected, e.g. directly connected or connected without any additional active components therebetween, to the floating diffusion area FD1, and an opposite end of the photo transistor P1 (e.g. a source or a drain) may be connected, e.g. directly connected or connected without any additional active component therebetween, to one end of a photo transistor P2. The photo transistor P1 may integrate charges generated at a substrate, for example, a body of the photo transistor P1 with light from the light signal RL incident onto the pixel PXa, based on a photo gate signal PG1. The photo gate signal PG1 may be or include a modulation signal, the phase of which is the same as or different from a phase of the light signal EL described with reference to FIG. 1. The photo gate signal PG1 may be activated and/or enabled during an integration period (interval) in which the light signal EL is emitted from the light source 112 and the light signal RL is incident onto the pixel array 121 and may be deactivated and/or disabled in a time except for/outside of the integration period. Charges that are integrated and stored by the photo transistor P1 may be transferred/transmitted to the floating diffusion area FD1. The floating diffusion area FD1 may be or include an n-type impurity area in the substrate where the pixel array 121 is implemented, and may be also referred to as a “floating diffusion node”.

The reset transistor R1 may be connected between, e.g. directly connected or connected without any active components therebetween the floating diffusion area FD1 and a power supply voltage VDD. The reset transistor R1 may electrically connect the floating diffusion area FD1 to the power supply voltage VDD based on a reset gate signal RG. The reset transistor R1 may drive a voltage level of the floating diffusion area FD1 to the power supply voltage VDD based on the reset gate signal RG, and may remove charges stored in the floating diffusion area FD1.

The source follower transistor SF1 may be connected between, e.g. directly connected or connected without any active components therebetween the power supply voltage VDD and the selection transistor SE1. A gate electrode of the source follower transistor SF1 may be connected, e.g. directly connected, to the floating diffusion area FD1. The source follower transistor SF1 may output an output signal OUT1 based on a voltage level of the floating diffusion area FD1. The selection transistor SE1 may be connected between, e.g. directly connected or connected without any active components therebetween the source follower transistor SF1 and an output line (not illustrated). The selection transistor SE1 may output the output signal OUT1 to the output line based on a selection signal SEL.

The tap TAP2 may include the photo transistor P2 and the readout circuit RO. The readout circuit RO may include a floating diffusion area FD2, a reset transistor R2, a source follower transistor SF2, and a selection transistor SE2. A configuration and an operation of the tap TAP2 may be substantially the same as the configuration and the operation of the tap TAP1 except that a photo gate signal PG2 is applied to the tap TAP2. A phase of the photo gate signal PG2 that is applied to a gate electrode of the photo transistor P2 in the tap TAP2 may be different from, e.g. opposite to, a phase of the photo gate signal PG1 that is applied to the gate electrode of the photo transistor P1 in the tap TAP1. Except for a different phase, as in the photo gate signal PG1, the photo gate signal PG2 may be activated during the integration period and may be deactivated in the time except for/outside of the integration period. The tap TAP1 may output the output signal OUT1 based on the photo gate signal PG1. The tap TAP2 may output an output signal OUT2 based on the photo gate signal PG2, the phase of which is different from, e.g. opposite to, the phase of the photo gate signal PG1. For example, a voltage level difference between the output signals OUT1 and OUT2 may indicate a distance between the electronic device 100 and an object.

An example is illustrated in FIG. 2A as all the transistors of the pixel PXa are implemented with NMOS transistors, but the transistors of the pixel PXa may be implemented with PMOS transistors or a combination of NMOS transistors and PMOS transistors. The type of the transistors of the pixel PXa is not limited to the example illustrated in FIG. 2A.

FIG. 2B illustrates a circuit diagram of a pixel of FIG. 1. FIG. 2B may correspond to a homogenous pixel. A description will be focused on a difference between a pixel PXb of FIG. 2B and the pixel PXa of FIG. 2A. The tap TAP1 may further include a storage transistor S1. The storage transistor S1 may be connected between, e.g. directly connected or connected without any active components therebetween the photo transistor P1 and the floating diffusion area FD1. For example, charges that are integrated and stored by the photo transistor P1 may not be directly transferred to the floating diffusion area FD1. Instead, based on a storage gate signal SG, the storage transistor S1 may store charges integrated by the photo transistor P1 and may transfer the stored charges to the floating diffusion area FD1. For example, the storage transistor S1 may be also referred to as a “transfer (transmission) transistor”. The tap TAP2 may further include a storage transistor S2 that is connected between, e.g. directly connected or connected without any additional active components therebetween one end of the photo transistor P2 and the floating diffusion area FD2. The storage transistor S2 may be implemented substantially the same as the storage transistor S1 and may operate substantially the same as the storage transistor S1.

A difference between the taps TAP1 and TAP2 in the pixel PXb of FIG. 2B and the taps TAP1 and TAP2 in the pixel PXa of FIG. 2A includes the storage transistors S1 and S2. The taps TAP1 and TAP2 of the pixel PXa may directly store charges integrated by the photo transistors P1 and P2 in the floating diffusion areas FD1 and FD2. The taps TAP1 and TAP2 of the pixel PXb may directly store charges integrated by the photo transistors P1 and P2 in the storage transistors S1 and S2.

The pixel PXb may include the storage transistors S1 and S2, thus improving a reset noise or a read noise (also referred to as “RN”). The reset noise or the read noise of the pixel PXb may be lower or smaller than the reset noise or the read noise of the pixel PXa. The pixel PXa may not include the storage transistors S1 and S2. A full well capacity (FWC) of each of the floating diffusion areas FD1 and FD2 of the pixel PXa may be greater than a FWC of each of the floating diffusion areas FD1 and FD2 of the pixel PXb.

FIG. 3A illustrates a circuit diagram of a pixel of FIG. 1. A pixel HPX1a may include the tap TAP1 that does not include the storage transistor S1 of the pixel PXa and the tap TAP2 that includes the storage transistor S2 of the pixel PXb. The pixel HPX1a may be also referred to as a “hybrid pixel”, and the letter “H” may refer to “hybrid”. The tap TAP1 of the pixel HPX1a may be implemented substantially the same as each of the taps TAP1 and TAP2 of the pixel PXa and may operate substantially the same as each of the taps TAP1 and TAP2 of the pixel PXa. The tap TAP2 of the pixel HPX1a may be implemented substantially the same as each of the taps TAP1 and TAP2 of the pixel PXb and may operate substantially the same as each of the taps TAP1 and TAP2 of the pixel PXb.

For example, the FWC of the floating diffusion area FD1 of the tap TAP1 may be greater than the FWC of the floating diffusion area FD2 of the tap TAP2. In a case of a high-illuminance condition (in the case where a light incident onto the pixel array 121 is strong and/or an external light is strong), operating the tap TAP1 instead of the tap TAP2 may be more advantageous and/or appropriate. The tap TAP2 may not directly store charges integrated by the photo transistor P2 in the floating diffusion area FD2. The tap TAP2 may store charges integrated by the photo transistor P2 in the storage transistor S2. Then, the tap TAP2 may store the charges stored in the storage transistor S2 in the floating diffusion area FD2. For example, a reset noise and/or a read noise of the output signal OUT2 of the tap TAP2 may be less than a reset noise and/or a read noise of the output signal OUT1 of the tap TAP1. In a case of a low-illuminance condition, e.g. in the case where a light incident onto the pixel array 121 is weak and/or an external light is weak, operating the tap TAP2 instead of the tap TAP1 may be more advantageous/appropriate.

FIG. 3B illustrates a circuit diagram of a pixel of FIG. 1. A description will be focused on a difference between a pixel HPX1b and the pixel HPX1a. The tap TAP2 may further include a transfer transistor T2. The tap TAP1 may not include a transfer transistor. The transfer transistor T2 may be connected between, e.g. directly connected or connected without any additional active components therebetween one end of the storage transistor S2 and the floating diffusion area FD2. The transfer transistor T2 may transfer charges stored in the storage transistor S2 to the floating diffusion area FD2 based on a transfer gate signal TG.

FIG. 3C illustrates a circuit diagram of a pixel of FIG. 1. A description will be focused on a difference between a pixel HPX1c and the pixel HPX1b. The tap TAP2 may include a storage diode SD2 instead of the storage transistor S2, and the tap TAP1 may not include a storage diode. As in the storage transistor S2, the storage diode SD2 may store charges integrated by the photo transistor P2. One end of the storage diode SD2 may be connected, e.g. directly connected, to one end of the photo transistor P2 and one end of the transfer transistor T2. An opposite end of the storage diode SD2 may be connected, e.g. directly connected, to a power supply voltage GND or VDD.

FIG. 3D illustrates a circuit diagram of a pixel of FIG. 1. A description will be focused on a difference between a pixel HPX1d and the pixels HPX1b and HPX1c. The tap TAP2 may include both the storage transistor S2 and the storage diode SD2. The tap TAP1 may not include either a storage diode or a storage transistor. Both the storage transistor S2 and the storage diode SD2 may store charges integrated by the photo transistor P2. For example, the storage diode SD2 may be implemented in the substrate where the pixel array 121 is implemented, so as to overlap the storage transistor S2 in a plan view. The storage transistor S2, the storage diode SD2, or a combination thereof may be also referred to as a “storage element”.

FIG. 3E illustrates a circuit diagram of a pixel of FIG. 1. A description will be focused on a difference between a pixel HPX1e and the pixel HPX1b. The pixel HPX1e may further include an overflow transistor OF connected to, e.g. directly connected or without any additional active components therebetween the overflow transistor OF and the power supply voltage VDD. The tap TAP1 may further include a transfer transistor T1 that is connected between, e.g. directly connected or connected without any additional active components therebetween the opposite end of the photo transistor P1 and the floating diffusion area FD1. The tap TAP1 may not include a transistor and/or another active component between, e.g. directly between, the photo transistor P1 and the transfer transistor T1. The tap TAP1 may not include a storage transistor. The tap TAP2 may further include a transfer transistor T21 that is connected between, e.g. directly connected or connected without any additional active components therebetween the opposite end of the photo transistor P2 and one end of the storage transistor S2. A transfer transistor T22 of the tap TAP2 may be implemented substantially the same as the transfer transistor T2 of each of the pixels HPX1b, HPX1c, and HPX1d and may operate substantially the same as the transfer transistor T2 thereof. A transfer gate signal TG2 may be the same as, or function in a similar manner as, the transfer gate signal TG of each of the pixels HPX1b, HPX1c, and HPX1d.

Based on an overflow gate signal OG, the overflow transistor OF may remove charges integrated by the photo transistors P1 and P2 in a time except for/outside of the integration period, and/or may discharge the charges to the power supply voltage VDD. In the time except for/outside of the integration period, the photo transistors P1 and P2 may integrate charges due to an external light. In the time except for/outside of the integration period, the transfer transistor T1 may prevent, or substantially prevent or reduce the amount of, charges integrated in the photo transistor P1 from being transferred to the floating diffusion area FD1 based on a transfer gate signal TG1. Based on the transfer gate signal TG1, the transfer transistor T1 may electrically connect the opposite end of the photo transistor P1 to the floating diffusion area FD1 during the integration period, and may disconnect the opposite end of the photo transistor P1 from the floating diffusion area FD1 in the time except for/outside of the integration period. Based on the transfer gate signal TG1, in the time except for/outside of the integration period the transfer transistor T21 may prevent or substantially prevent charges integrated in the photo transistor P2 from being transferred to the storage transistor S2. The transfer transistor T21 may electrically connect the opposite end of the photo transistor P2 to one end of the storage transistor S2 during the integration period based on the transfer gate signal TG1 and may disconnect the opposite end of the photo transistor P1 from the one end of the storage transistor S2 in the time except for/outside of the integration period.

FIGS. 3F and 3G illustrate circuit diagrams of a pixel of FIG. 1. A description will be focused on a difference between pixels HPX1f and HPX1g and the pixel HPX1e. Each of the pixels HPX1f and HPX1g may further include a photoelectric conversion element PD. Below, a photo diode will be described as an example of the photoelectric conversion element PD; however, inventive concepts are not limited thereto, and a photo diode, a photo transistor, a photo gate, a pinned photo diode, or a combination thereof may be used as the photoelectric conversion element PD.

The photoelectric conversion element PD may generate and accumulate charges corresponding to the light signal RL. The charges generated by the photoelectric conversion element PD may be distributed into the photo transistors P1 and P2. For example, a ratio of the amount of charges stored in the photo transistor P1 from among the charges generated by the photoelectric conversion element PD to the amount of charges stored in the photo transistor P2 from among the charges generated by the photoelectric conversion element PD may be determined depending on a phase difference between the light signal RL and the photo gate signals PG1 and PG2. For example, the photoelectric conversion element PD may be implemented in the same substrate where the pixel array 121 is implemented, so as to overlap the photo transistors P1 and P2 in a plan view. Referring to FIG. 3G, the photoelectric conversion element PD may be connected between common ends of the photo transistors P1 and P2 and the power supply voltage GND.

FIG. 3H illustrates a circuit diagram of a pixel of FIG. 1. A description will be focused on a difference between a pixel HPX1h and the pixel HPX1g. The floating diffusion area FD1 of the tap TAP1 and the floating diffusion area FD2 of the tap TAP2 may be electrically connected. The pixel HPX1h may include a readout circuit connected, e.g. directly connected or connected without an active element therebetween, to a floating diffusion area FD. The readout circuit may include a reset transistor R, a source follower transistor SF, and a selection transistor SE. The floating diffusion area FD and/or the readout circuit may be shared by the taps TAP1 and TAP2 corresponding to an intra-pixel. There may be no select gate or transfer gate in TAP1. An example is illustrated in FIG. 3H as the tap TAP1 includes the readout circuit; however, the tap TAP2 may include the readout circuit, or both the taps TAP1 and TAP2 may include the readout circuits, respectively. The readout circuit of the pixel HPX1h may be implemented substantially the same as the readout circuit described with reference to FIG. 3A and may operate substantially the same as the readout circuit described with reference to FIG. 3A.

FIG. 3I illustrates a circuit diagram of a pixel of FIG. 1. A description will be focused on a difference between pixels HPX1i[n] and HPX1i[n+1] and the pixels HPX1g and HPX1h. Here, “n” may indicate a number, e.g. an integer, of the pixel HPX1i, and the pixel HPX1i[n] and the pixel HPX1i[n+1] may be adjacent to each other along the row direction. A floating diffusion area FD[n+1] of the tap TAP2 of the pixel HPX1i[n] and the floating diffusion area FD[n+1] of the tap TAP1 of the pixel HPX1i[n+1] may be electrically connected. The pixels HPX1i[n] and HPX1i[n+1] may include a readout circuit connected to the floating diffusion area FD[n+1]. The readout circuit may include the reset transistor R, the source follower transistor SF, and the selection transistor SE. The floating diffusion area FD[n+1] and the readout circuit may be shared by an inter-pixel (e.g., the pixels HPX1i[n] and HPX1i[n+1]), and by the tap TAP2 of the pixel HPX1i[n] and the tap TAP1 of the pixel HPX1i[n+1]. The pixel HPX1i[n] and a pixel HPX1i[n−1] (not illustrated) may be adjacent to each other along the row direction. The tap TAP1 of the pixel HPX1i[n] and the tap TAP2 of the pixel HPX1i[n−1] may also share the floating diffusion area FD[n] and the readout circuit. The tap TAP2 of the pixel HPX1i[n+1] and the tap TAP1 of a pixel HPX1i[n+2] (not illustrated) may also share a floating diffusion area and a readout circuit.

FIGS. 3J and 3K illustrate circuit diagrams of a pixel of FIG. 1. A description will be focused on a difference between pixels HPX1j and HPX1k and the pixel HPX1g. Referring to FIG. 3J, the tap TAP1 of the pixel HPX1j may further include a dual conversion transistor DC connected between, e.g. directly connected or connected without any additional active components therebetween the floating diffusion area FD1 and the power supply voltage GND. There may not be a storage gate or a transfer gate in TAP1. Referring to FIG. 3K, the tap TAP1 of the pixel HPX1k may further include the dual conversion transistor DC connected between, e.g. directly connected or connected without any additional active components therebetween the floating diffusion area FD1 and one end of the reset transistor R1. The dual conversion transistor DC may be turned on or turned off based on a dual conversion gate signal DG. The dual conversion transistor DC may change/adjust a capacitance of the floating diffusion area FD1, for example, the FWC, based on the dual conversion gate signal DG. For example, the dual conversion transistor DC may operate as a MOS capacitor. For another example, the dual conversion transistor DC may operate as a switch, and the tap TAP1 may further include a capacitor (not illustrated) connected or directly connected between the dual conversion transistor DC and the power supply voltage GND or VDD.

FIGS. 3L and 3M illustrate circuit diagrams of a pixel of FIG. 1. A description will be focused on a difference between pixels HPX1l and HPX1m and the pixel HPX1j. Referring to FIG. 3L, the tap TAP2 of the pixel HPX1l may further include the dual conversion transistor DC connected between, e.g. directly connected or connected without any additional active components therebetween the floating diffusion area FD2 and the power supply voltage GND. Referring to FIG. 3M, the tap TAP2 of the pixel HPX1m may further include the dual conversion transistor DC connected between the floating diffusion area FD2 and one end of the reset transistor R2. An example is illustrated in FIGS. 3J to 3M as one of the taps TAP1 and TAP2 includes the dual conversion transistor DC, but the taps TAP1 and TAP2 may include the dual conversion transistors DC, respectively.

FIG. 3N illustrates a circuit diagram of a pixel of FIG. 1. A description will be focused on a difference between a pixel HPX1n and the pixel HPX1h. The pixel HPX1n may further include the dual conversion transistor DC connected between, e.g. directly connected the floating diffusion area FD and the power supply voltage GND. There may not be any additional passive components such as resistors or capacitors, and/or additional active components such as transistors, between the dual conversion transistor DC and the floating diffusion area FD. The dual conversion transistor DC may be connected between, e.g. directly connected or connected without any active and/or passive components therebetween the floating diffusion area FD and the one end of the reset transistor R (refer to the dual conversion transistor DC of the pixel HPX1k of FIG. 3K).

FIG. 3O illustrates a circuit diagram of a pixel of FIG. 1. A description will be focused on a difference between pixels HPX1o[n] and HPX1o[n+1] and the pixels HPX1i[n] and HPX1i[n+1]. The pixel HPX1o[n] may further include the dual conversion transistor DC connected between, e.g. directly connected or connected without any additional active components such as transistors between the dual conversion transistor DC, the floating diffusion area FD[n], and the power supply voltage GND. The pixel HPX1o[n+1] may further include the dual conversion transistor DC connected between, e.g. directly connected or connected without any additional active components therebetween the floating diffusion area FD[n+1] and the power supply voltage GND. The dual conversion transistor DC may be connected, e.g. directly connected, between a floating diffusion area and one end of the reset transistor R (refer to the dual conversion transistor DC of the pixel HPX1k of FIG. 3K).

FIG. 3P illustrates a circuit diagram of a pixel of FIG. 1. A description will be focused on a difference between pixels HPX1p[n] and HPX1p[n+1] and the pixel HPX1h. Here, “n” may indicate a number, e.g. an integer number, of the pixel HPX1p, and the pixel HPX1p[n] and the pixel HPX1p[n+1] may be adjacent to each other along the column direction. The pixel HPX1p[n] may further include the dual conversion transistor DC connected, e.g. directly connected, to the floating diffusion area FD[n]. The pixel HPX1p[n+1] may further include the dual conversion transistor DC connected, e.g. directly connected, to the floating diffusion area FD[n+1]. One end of the dual conversion transistor DC in the pixel HPX1p[n] and one end of the dual conversion transistor DC in the pixel HPX1p[n+1] may be electrically connected, e.g. directly connected.

FIG. 3Q illustrates a circuit diagram of a pixel of FIG. 1. A description will be focused on a difference between a pixel HPX1q and the pixel HPX1g. The pixel HPX1q may include four taps TAP1 to TAP4. The number of taps included in a pixel of inventive concepts is two or more and is not limited to “2” or “4” described above.

The taps TAP1 to TAP4 may share the photoelectric conversion element PD. One ends of photo transistors P1 to P4 of the taps TAP1 to TAP4, one end of the photoelectric conversion element PD, and one end of the overflow transistor OF may be electrically connected, e.g. directly electrically connected. The photo transistors P1 to P4 may respectively integrate charges based on photo gate signals PG1 to PG4. The photo gate signal PG1 may be or include a modulation signal, the phase of which is the same as or different from a phase of the light signal EL. Phases of the photo gate signals PG1, PG2, PG3, and PG4 may be different. Except for the photo gate signals PG1 and PG3, the taps TAP1 and TAP3 may be implemented substantially the same as the tap TAP1 of the pixel HPX1g of FIG. 3G. Except for the photo gate signals PG2 and PG4, the taps TAP2 and TAP4 may be implemented substantially the same as the tap TAP2 of the pixel HPX1g of FIG. 3G.

FIG. 3R illustrates a circuit diagram of a pixel of FIG. 1. A description will be focused on a difference between a pixel HPX1r and the pixel HPX1q. The photo transistors P1 and P3 of the taps TAP1 and TAP3 may integrate charges based on the same photo gate signal PG1. The photo transistors P2 and P4 of the taps TAP2 and TAP4 may integrate charges based on the same photo gate signal PG2. The pixel HPX1r may include four taps TAP1 to TAP4 but may operate substantially the same as the pixel HPX1g including two taps TAP1 and TAP2.

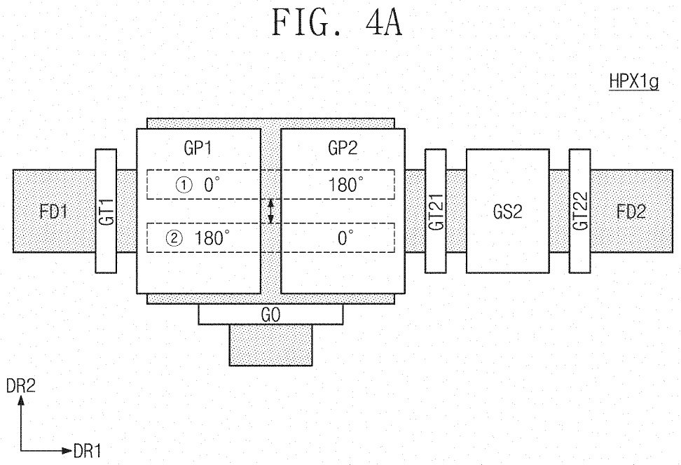

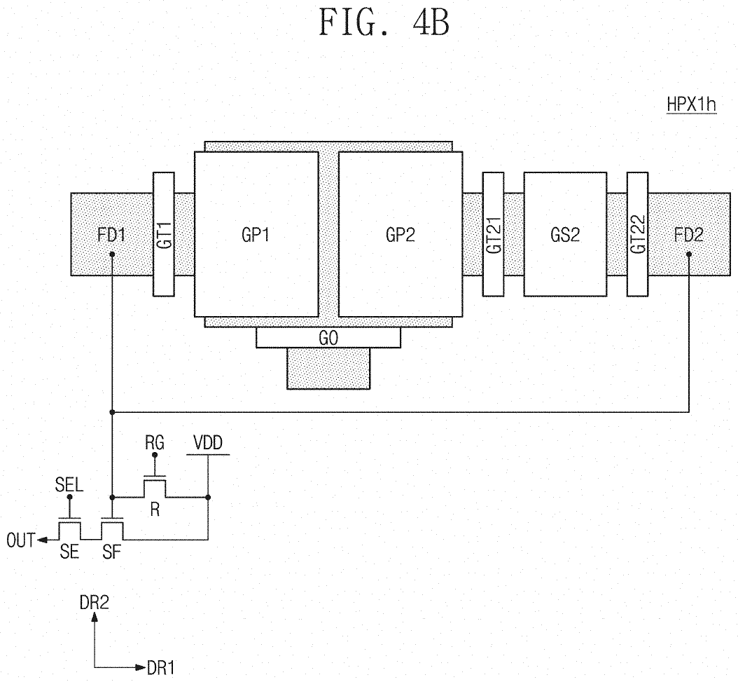

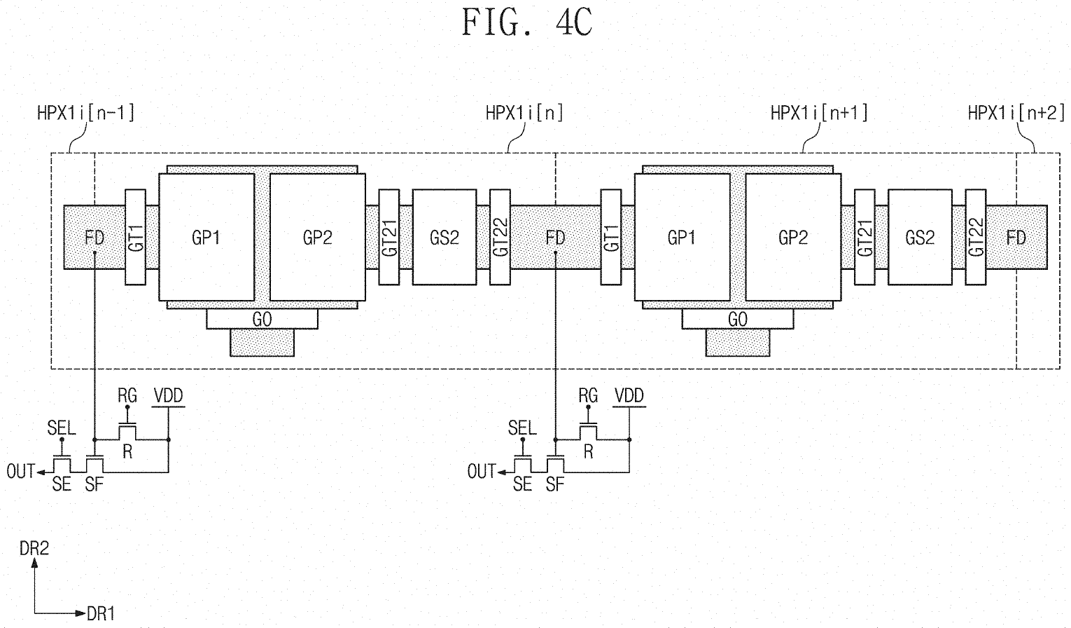

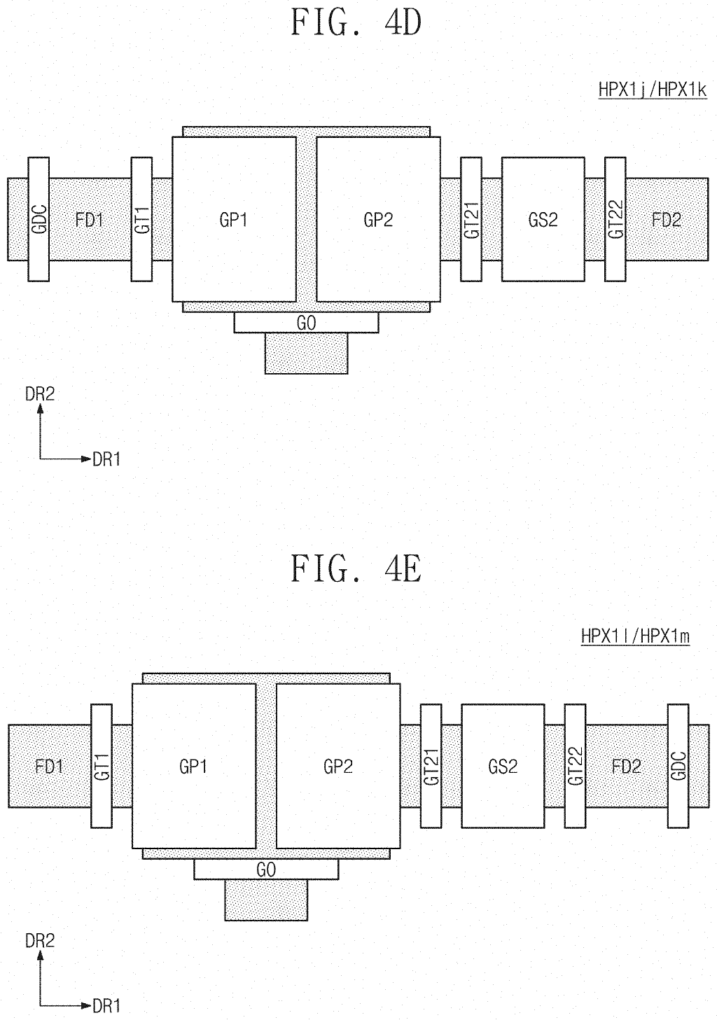

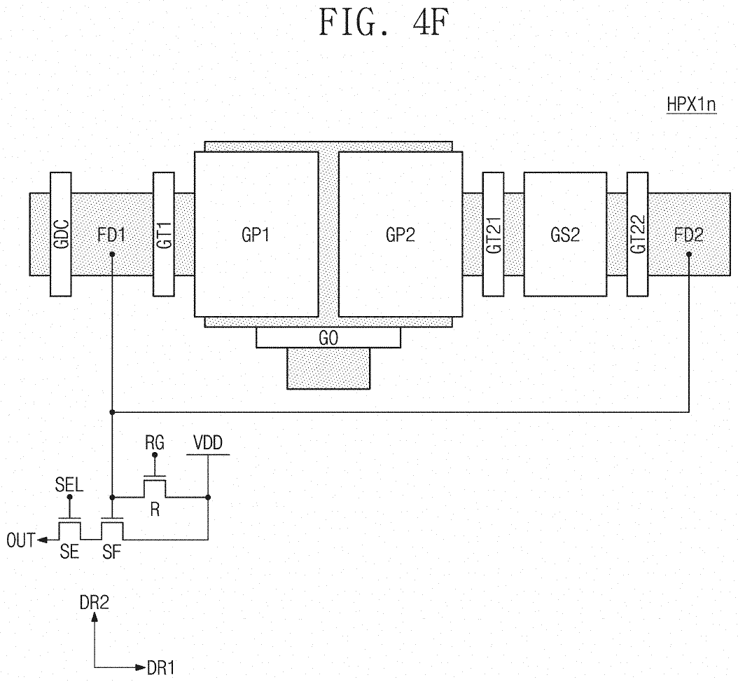

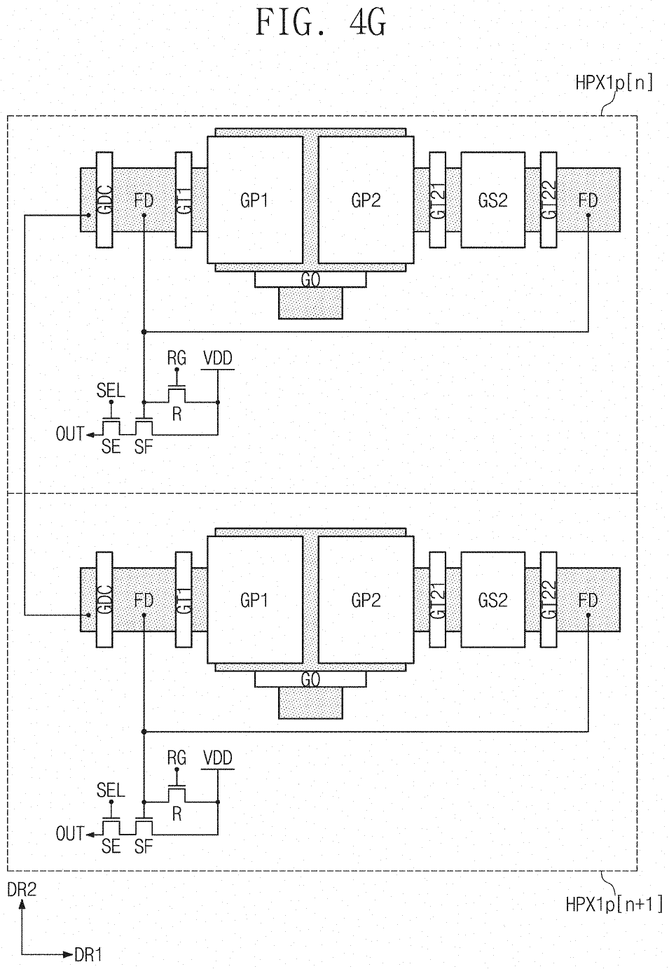

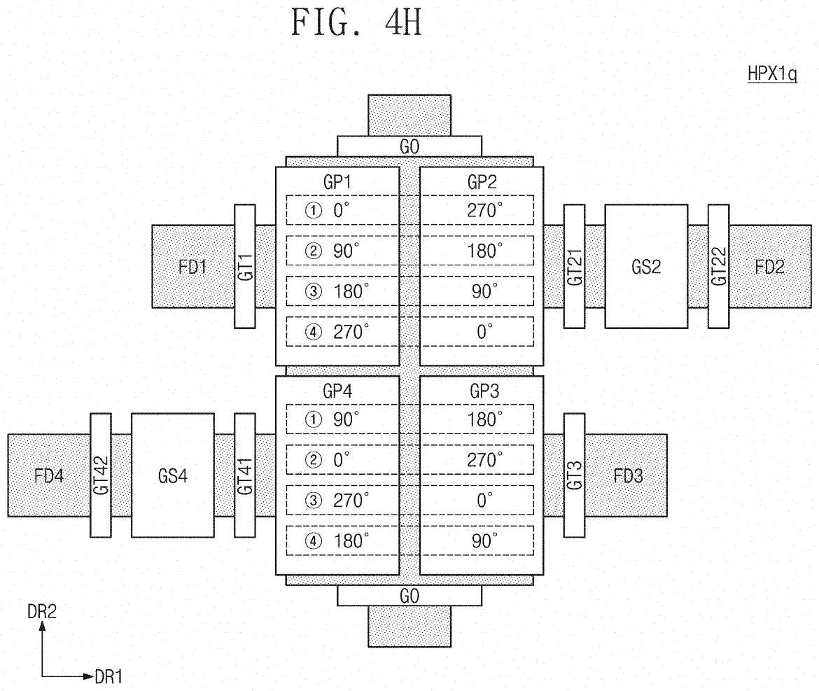

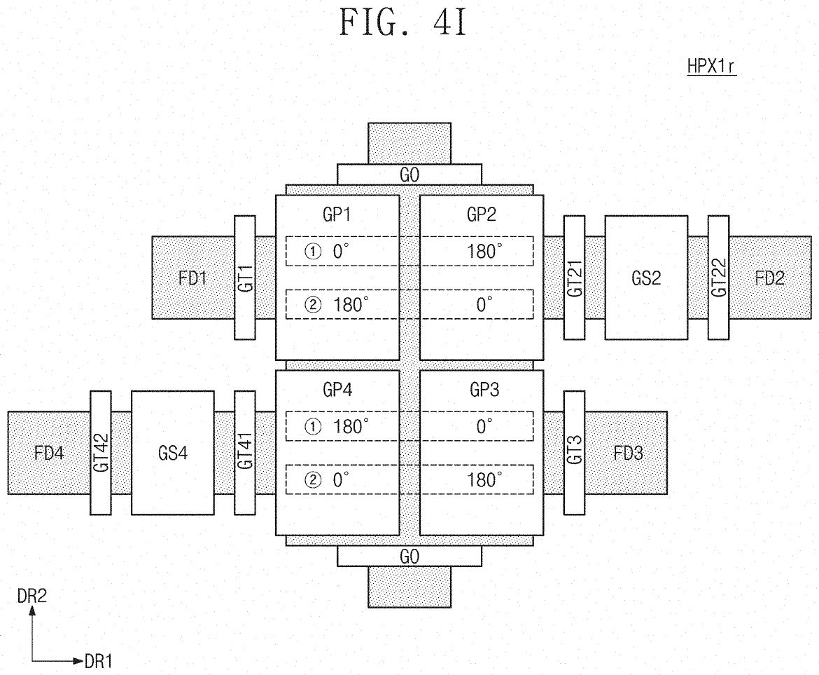

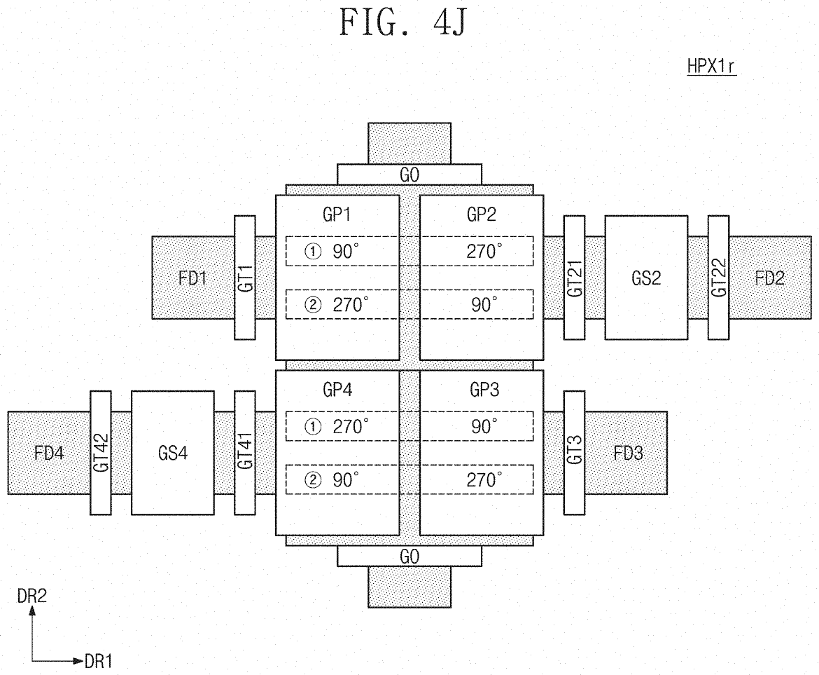

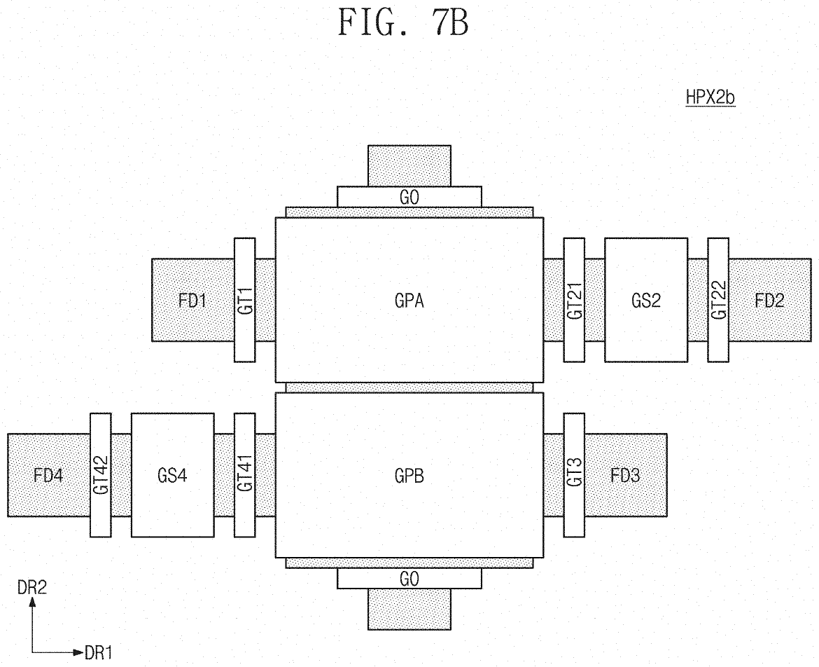

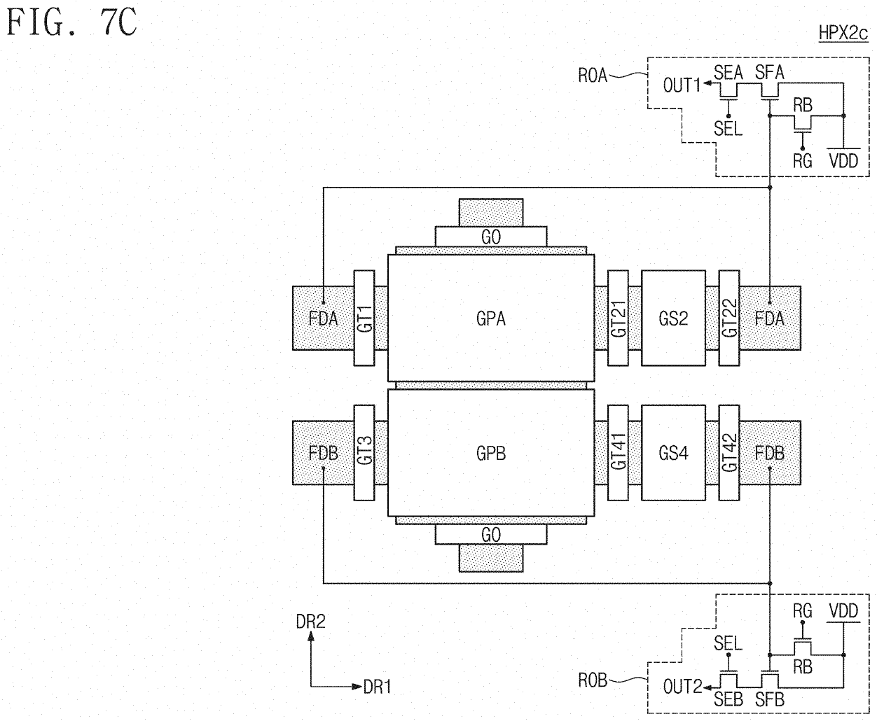

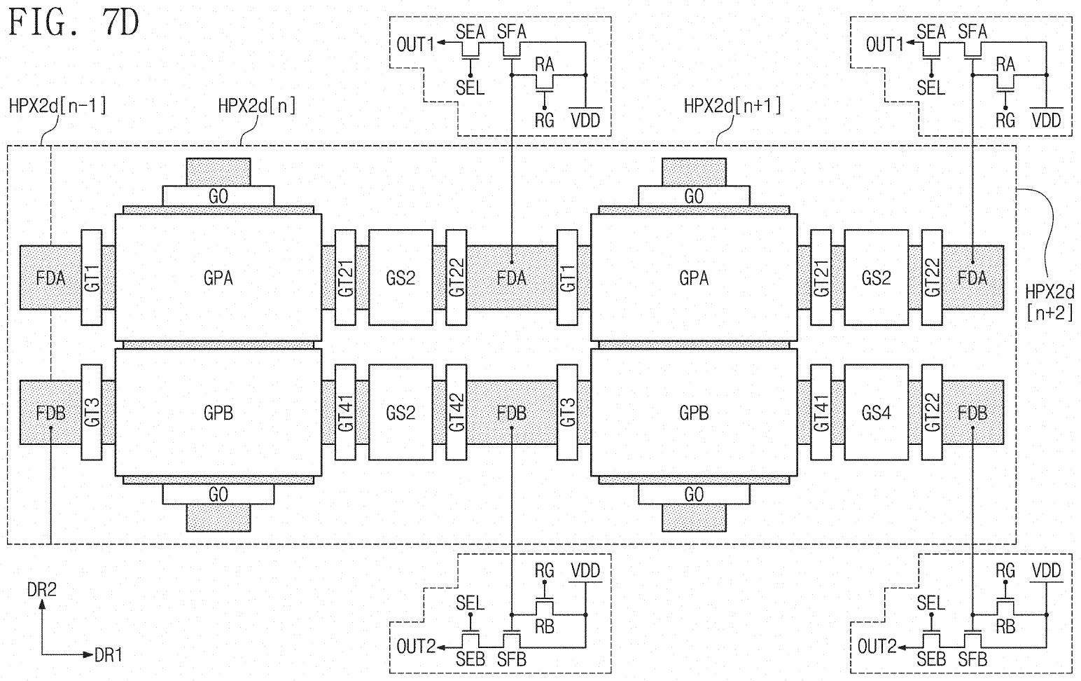

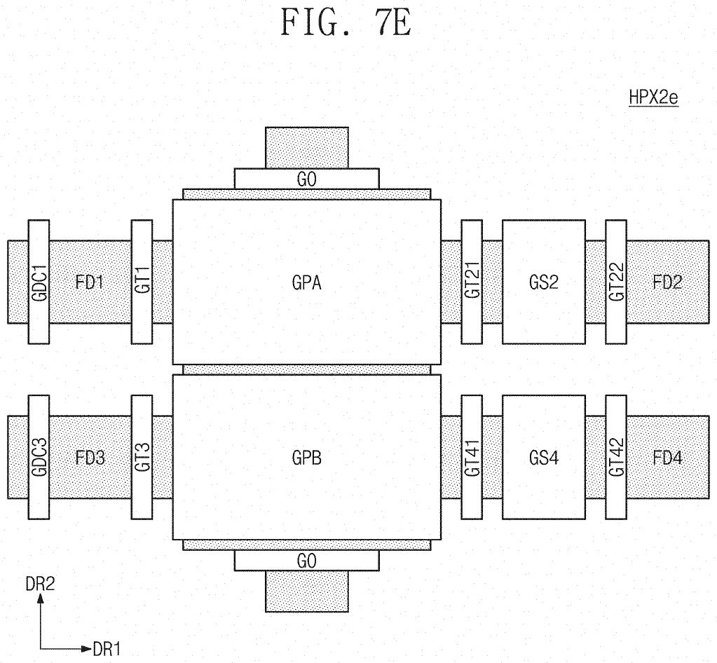

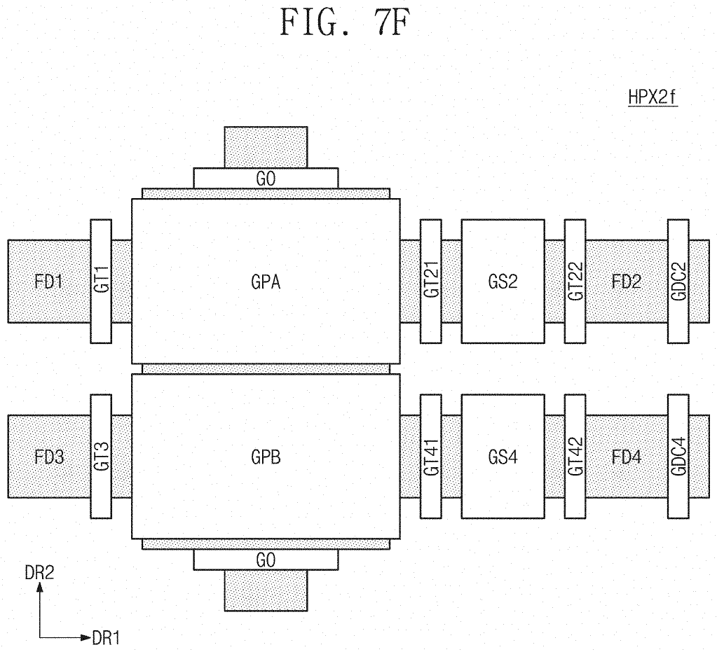

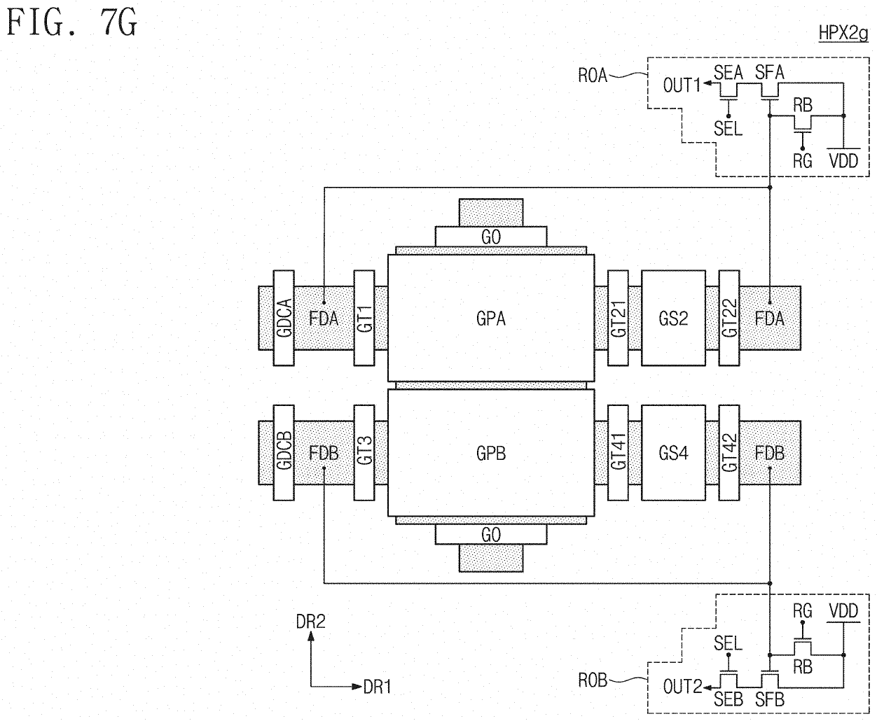

FIG. 4A illustrates a layout of a pixel of FIG. 3G. The transistors R1, R2, SF1, SF2, SE1, and SE2 corresponding to the read circuits of the pixel HPX1g are not illustrated in FIG. 4A. In FIGS. 4A to 4J and FIGS. 7A to 7G, a direction DR1 and a direction DR2 may be perpendicular to each other. The directions DR1 and DR2 may be perpendicular to a direction that faces the pixel array 121 in a plan view. For example, the directions DR1 and DR2 may correspond to the row and column directions in which pixels of the pixel array 121 are arranged; however, inventive concepts are not limited thereto. Directions DR1 and DR2 may be parallel to a surface of a substrate upon which the pixel array 121 is formed. Drains and/or sources of transistors may be formed/disposed in shading areas of FIGS. 4A to 4J and FIGS. 7A to 7G.

Gate electrodes GP1 and GP2 of the photo transistors P1 and P2 may be disposed adjacent to each other along the direction DR1. A gate electrode GO of the overflow transistor OF may be disposed adjacent to the gate electrodes GP1 and GP2 along the direction DR2. A gate electrode GT1 of the transfer transistor T1 may be disposed adjacent to the gate electrode GP1 along the direction DR1. The floating diffusion area FD1 may be disposed adjacent to the gate electrode GT1 along the direction DR1. A gate electrode GT21 of the transfer transistor T21 may be disposed adjacent to the gate electrode GP2 along the direction DR1. A gate electrode GS2 of the storage transistor S2 may be disposed adjacent to the gate electrode GT21 along the direction DR1. A gate electrode GT22 of the transfer transistor T22 may be disposed adjacent to the gate electrode GS2 along the direction DR1. The floating diffusion area FD2 may be disposed adjacent to the gate electrode GT22 along the direction DR1. Although not illustrated in FIG. 4A, a photoelectric conversion area PD may be disposed or formed in the substrate so as to overlap the gate electrodes GP1 and GP2 in a plan view. The storage diode SD2 (refer to FIG. 3D) may be disposed or formed in the substrate so as to overlap the gate electrode GS2 in a plan view.

The photo gate signal PG1 having a phase difference of 0 degrees with respect to the light signal EL may be applied to the gate electrode GP1, and the photo gate signal PG2 having a phase difference of 180 degrees with respect to the light signal EL may be applied to the gate electrode GP2 (\textcircled{1}). The tap TAP1 may output the output signal OUT1 having phase information of 0 degrees based on a voltage level of the floating diffusion area FD1. The tap TAP2 may output the output signal OUT2 having phase information of 180 degrees based on a voltage level of the floating diffusion area FD2.

Then, the photo gate signal PG1 having a phase difference of 180 degrees with respect to the light signal EL may be applied to the gate electrode GP1, and the photo gate signal PG2 having a phase difference of 0 degrees with respect to the light signal EL may be applied to the gate electrode GP2 (\textcircled{2}). The photo gate signals PG1 and PG2 may be shuffled. The tap TAP1 may output the output signal OUT1 having phase information of 180 degrees based on a voltage level of the floating diffusion area FD1. The tap TAP2 may output the output signal OUT2 having phase information of 0 degrees based on a voltage level of the floating diffusion area FD2.

In some example embodiments, the processor 130 may selectively synthesize or interpolate the output signal OUT1 having phase information of 0 degrees from the tap TAP1, the output signal OUT1 having phase information of 180 degrees from the tap TAP1, the output signal OUT2 having phase information of 180 degrees from the tap TAP2, and the output signal OUT2 having phase information of 0 degrees from the tap TAP2.

When a value of an amplitude/intensity of the light signal RL or the output signal OUT2 is less than a first threshold value and/or a value of an intensity of the light signal RL or the output signal OUT2 is greater than a second threshold value (e.g. in a high-illuminance environment where an external light is relatively strong), the processor 130 may use only the output signal OUT1 of the tap TAP1 including the phase information of both 0 degrees and 180 degrees for calculating a depth. When the value of the amplitude/intensity is greater than a third threshold value and/or the value of the intensity is less than a fourth threshold value (e.g. in a low-illuminance environment where an external light is relatively weak), the processor 130 may use only the output signal OUT2 of the tap TAP2 including the phase information of both 0 degrees and 180 degrees for calculating a depth. When the value of the amplitude/intensity is between the first and third threshold values and/or the value of the intensity is between the second and fourth threshold value, the processor 130 may use the output signal OUT1 of the tap TAP1 including the phase information of 0 degrees and 180 degrees and the output signal OUT2 of the tap TAP2 including the phase information of 0 degrees and 180 degrees for calculating a depth.

FIG. 4B illustrates a layout of a pixel of FIG. 3H. A description will be focused on a difference between a layout of the pixel HPX1h and the layout of the pixel HPX1g. A wire, e.g. a conductive wire integrated within the transistors, that electrically connects the floating diffusion area FD1 of the tap TAP1 to the floating diffusion area FD2 of the tap TAP2 may be provided on the pixel HPX1h or the pixel array 121. The transistors R, SF, and SE corresponding to the readout circuit are illustrated as circuit-level transistors.

FIG. 4C illustrates a layout of a pixel of FIG. 3H. A description will be focused on a difference between a layout of the pixels HPX1i[n] and HPX1i[n+1] and the layout of the pixel HPX1g. The tap TAP2 of the pixel HPX1i[n] and the tap TAP1 of the pixel HPX1i[n+1] may share the floating diffusion area FD. The transistors R, SF, and SE correspond to the readout circuit connected to the floating diffusion area FD are illustrated as circuit-level transistors.

FIG. 4D illustrates a layout of each of pixels of FIGS. 3J and 3K. A description will be focused on a difference between a layout of each of the pixels HPX1j and HPX1k and the layout of the pixel HPX1g. A gate electrode GDC of the dual conversion transistor DC may be disposed adjacent to the floating diffusion area FD1 along the direction DR1. FIG. 4E illustrates a layout of each of pixels of FIGS. 3L and 3M. A description will be focused on a difference between a layout of each of the pixels HPX1l and HPX1m and the layout of the pixel HPX1g. The gate electrode GDC of the dual conversion transistor DC may be disposed adjacent to the floating diffusion area FD2 along the direction DR1.

FIG. 4F illustrates a layout of a pixel of FIG. 3N. A description will be focused on a difference between a layout of the pixel HPX1n and the layout of each of the pixels HPX1j and HPX1k. A wire, e.g. a conductive wire integrated within the transistors, that electrically connects the floating diffusion area FD1 of the tap TAP1 to the floating diffusion area FD2 of the tap TAP2 may be provided on the pixel HPX1n or the pixel array 121. The transistors R, SF, and SE corresponding to the readout circuit connected to the floating diffusion area FD are illustrated as circuit-level transistors.

FIG. 4G illustrates a layout of each of pixels of FIG. 3P. A description will be focused on a difference between a layout of the pixels HPX1p[n] and HPX1p[n+1] and the layout of the pixel HPX1n. A wire, e.g. a conductive wire integrated within the transistors, that electrically connects one end of the dual conversion transistor DC in the pixel HPX1p[n] and one end of the dual conversion transistor DC in the pixel HPX1p[n+1] may be provided on the pixels HPX1p[n] and HPX1p[n+1] or the pixel array 121.

FIG. 4H illustrates a layout of a pixel of FIG. 3Q. A description will be focused on a difference between a layout of the pixel HPX1q and the layout of the pixel HPX1g. Gate electrodes GP3 and GP4 of the photo transistors P3 and P4 may be disposed adjacent to each other along the direction DR1. The gate electrodes GP1 and GP4 may be disposed adjacent to each other along the direction DR2. The gate electrodes GP2 and GP3 may be disposed adjacent to each other along the direction DR2. The gate electrode GO of the overflow transistor OF may be disposed adjacent to the gate electrodes GP3 and GP4 along the direction DR2. A gate electrode GT3 of a transfer transistor T3 may be disposed adjacent to the gate electrode GP3 along the direction DR1. A floating diffusion area FD3 may be disposed adjacent to the gate electrode GP3 along the direction DR1. A gate electrode GT41 of a transfer transistor T41 may be disposed adjacent to the gate electrode GP4 along the direction DR1. A gate electrode GS4 of a storage transistor S4 may be disposed adjacent to the gate electrode GT41 along the direction DR1. A gate electrode GT42 of a transfer transistor T42 may be disposed adjacent to a gate electrode GS4 along the direction DR1. A floating diffusion area FD4 may be disposed adjacent to the gate electrode GT42 along the direction DR1. Although not illustrated in FIG. 4H, the photoelectric conversion area PD may be disposed or formed in the substrate so as to overlap the gate electrodes GP1 to GP4 in a plan view.

The photo gate signal PG1 having a phase difference of 0 degrees with respect to the light signal EL, the photo gate signal PG2 having a phase difference of 270 degrees with respect to the light signal EL, the photo gate signal PG3 having a phase difference of 180 degrees with respect to the light signal EL, and the photo gate signal PG4 having a phase difference of 90 degrees with respect to the light signal EL may be applied to the gate electrodes GP1 to GP4 (\textcircled{1}). As described above, the photo gate signals PG1 to PG4 may be mutually shuffled (\textcircled{2}, \textcircled{3}, \textcircled{4}). Each of the taps TAP1 to TAP4 may output an output signal having all phase information of 0 degrees, 90 degrees, 180 degrees, and 270 degrees.

FIGS. 4I and 4J illustrate layouts of a pixel of FIG. 3R. A layout of the pixel HPX1r may be substantially the same as the layout of the pixel HPX1q Referring to FIG. 4I, the photo gate signal PG1 having a phase difference of 0 degrees with respect to the light signal EL may be respectively applied to the gate electrodes GP1 and GP3, and the photo gate signal PG2 having a phase difference of 180 degrees with respect to the light signal EL may be respectively applied to the gate electrodes GP2 and GP4 (\textcircled{1}). Then, the photo gate signal PG1 having a phase difference of 180 degrees with respect to the light signal EL may be respectively applied to the gate electrodes GP1 and GP3, and the photo gate signal PG2 having a phase difference of 0 degrees with respect to the light signal EL may be respectively applied to the gate electrodes GP2 and GP4 (\textcircled{2}).

Referring to FIG. 4J, the photo gate signal PG1 having a phase difference of 90 degrees with respect to the light signal EL may be respectively applied to the gate electrodes GP1 and GP3, and the photo gate signal PG2 having a phase difference of 270 degrees with respect to the light signal EL may be respectively applied to the gate electrodes GP2 and GP4 (\textcircled{1}). Then, the photo gate signal PG1 having a phase difference of 270 degrees with respect to the light signal EL may be respectively applied to the gate electrodes GP1 and GP3, and the photo gate signal PG2 having a phase difference of 90 degree with respect to the light signal EL may be respectively applied to the gate electrodes GP2 and GP4 (\textcircled{2}).

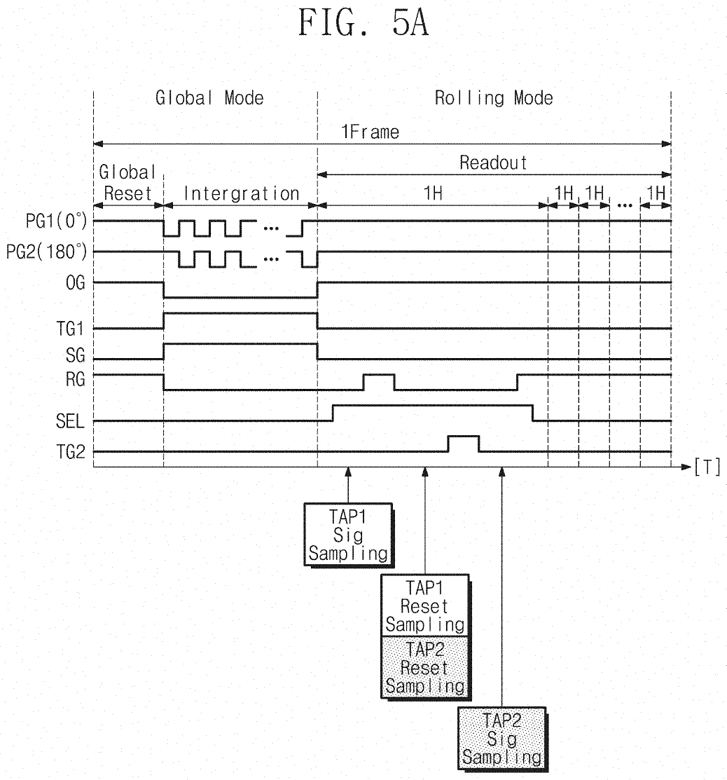

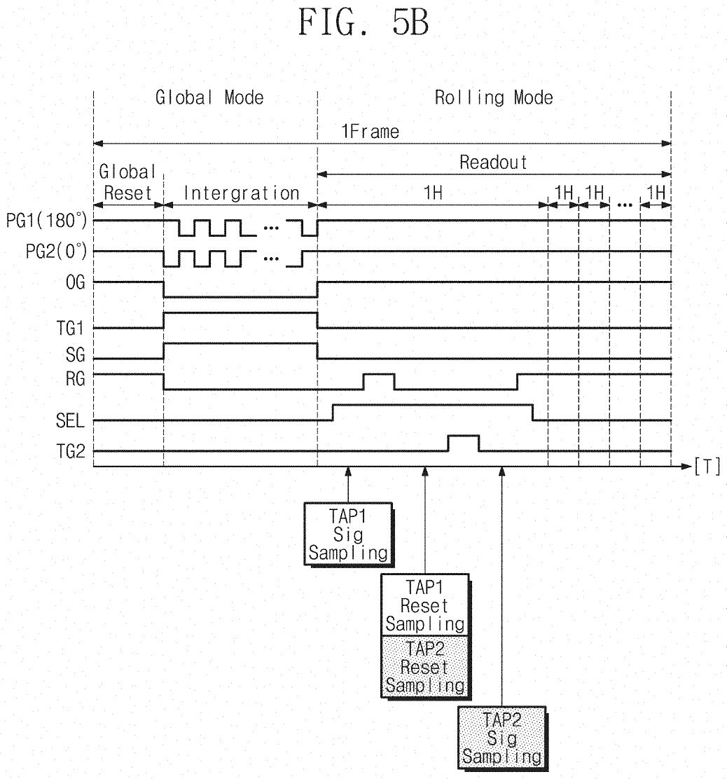

FIGS. 5A and 5B illustrate timing diagrams of signals that may be applied to a pixel of FIG. 3G. FIGS. 5A and 5B will be described with reference to the pixel HPX1g, but signals of FIGS. 5A and 5B may be applied to the above-described other pixels as well as the pixel HPX1g. The timing diagram of the signals of FIGS. 5A and 5B may indicate a period for reading one frame and may be repeated. A period for reading one frame may be divided into an interval of the global mode where all the pixels HPX1g of the pixel array 121 operate at the same time and an interval of the rolling mode where the pixels HPX1g operate in the unit of row.

During a global reset period of the global mode, all the pixels HPX1g of the pixel array 121 may be reset. For example, when the overflow gate signal OG is activated, the overflow transistor OF may remove charges integrated by the photo transistors P1 and P2. When the transfer gate signal TG1 is deactivated, the transfer transistor T1 may prevent charges from being transferred from the photo transistor P1 to the floating diffusion area FD1, and the transfer transistor T21 may prevent charges from being transferred from the photo transistor P2 to the storage transistor S2.

During the integration period of the global mode, the photo transistors P1 and P2 may integrate charges based on the photo gate signals PG1 and PG2. Referring to FIGS. 5A and 5B, the photo gate signals PG1 and PG2 may be shuffled (i.e., a phase change). The overflow gate signal OG may be deactivated, and the transfer gate signal TG1 may be activated. The charges integrated by the photo transistor P1 may be transferred to and stored in the floating diffusion area FD1 of the tap TAP1 through the transfer transistor T1. The charges integrated by the photo transistor P2 may be transferred to and stored in the storage transistor S2 of the tap TAP2 through the transfer transistor T21.

A readout period of the rolling mode may be divided into a plurality of 1H times. The 1H time may indicate a time or interval for reading the pixels HPX1g disposed along one row. First, a read operation of the read circuit of the tap TAP1 will be described.

After the integration period, the readout circuit of the tap TAP1 may output the output signal OUT1 corresponding to a signal level of the floating diffusion area FD1, which is determined depending on the charges integrated by the photo transistor P1 (TAP1 Sig Sampling). After the output signal OUT1 is output, as the reset gate signal RG is activated and is deactivated, the reset transistor R1 may be turned on and may be turned off, and thus, the floating diffusion area FD1 may be reset. After the floating diffusion area FD1 is reset, the readout circuit of the tap TAP1 may output the output signal OUT1 corresponding to a reset level of the floating diffusion area FD1 (TAP1 Reset Sampling). In some example embodiments, unlike the example illustrated in FIGS. 5A and 5B, the readout circuit of the tap TAP1 may output the output signal OUT1 corresponding to the reset level of the floating diffusion area FD1 that is reset during the global reset period before the integration period.

After the integration period, the readout circuit of the tap TAP2 may output the output signal OUT2 corresponding to a reset level of the floating diffusion area FD2 that is reset (TAP2 Reset Sampling). For example, the floating diffusion area FD2 may be reset by the reset gate signal RG that is applied to the tap TAP1. The “TAP2 Reset Sampling” time and the “TAP1 Sig Sampling” time may be the same as or different from each other. For another example, the floating diffusion area FD2 may be reset by a reset gate signal different from the reset gate signal RG that is applied to the tap TAP1. After the output signal OUT2 is output, as the transfer gate signal TG2 is activated and is deactivated, the transfer transistor T22 may be turned on and may be turned off, and thus, the charges stored in the storage transistor S2 may be transferred to the floating diffusion area FD2. After the transfer transistor T22 is turned on and is turned off, the readout circuit of the tap TAP2 may output the output signal OUT2 corresponding to a signal level of the floating diffusion area FD2, which is determined depending on the charges integrated by the photo transistor P2 (TAP2 Sig Sampling).

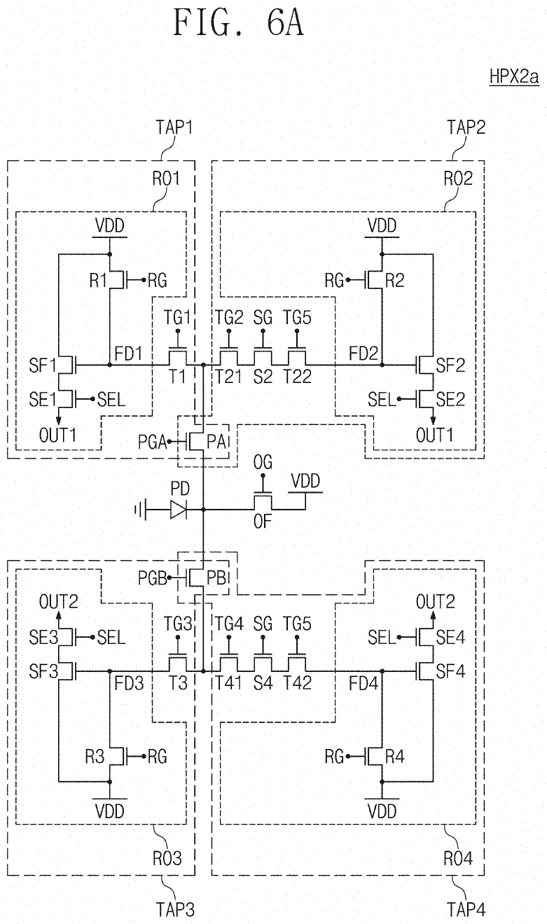

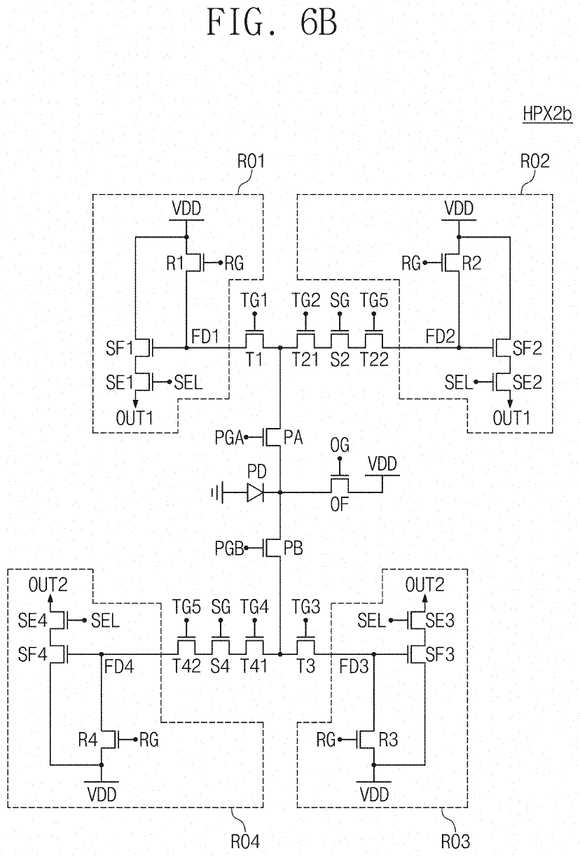

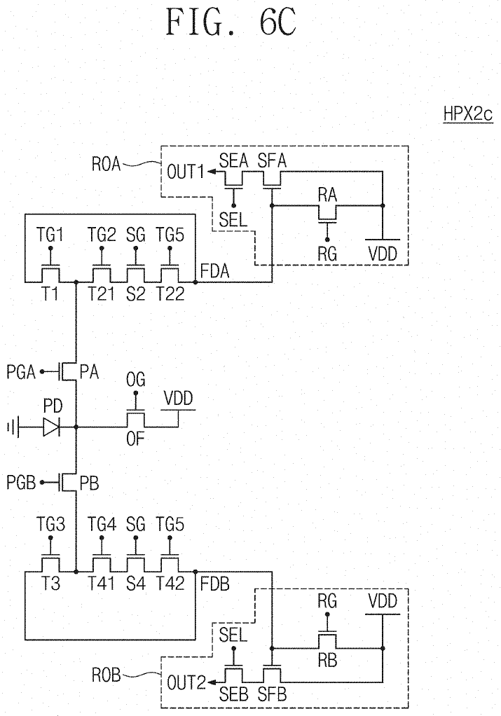

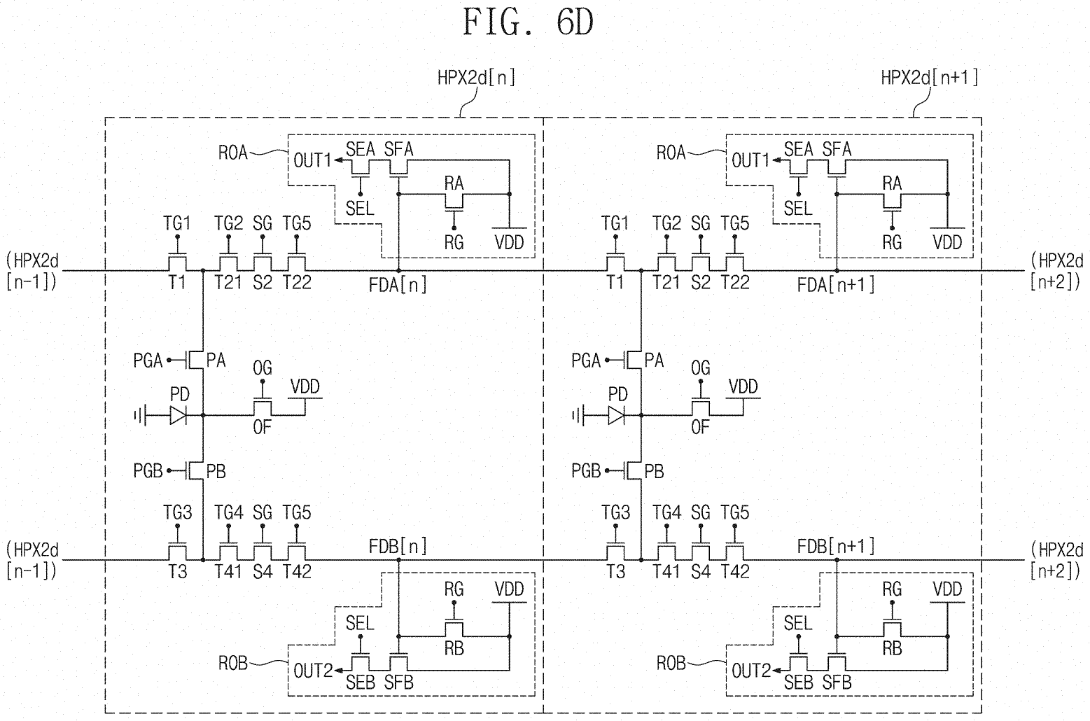

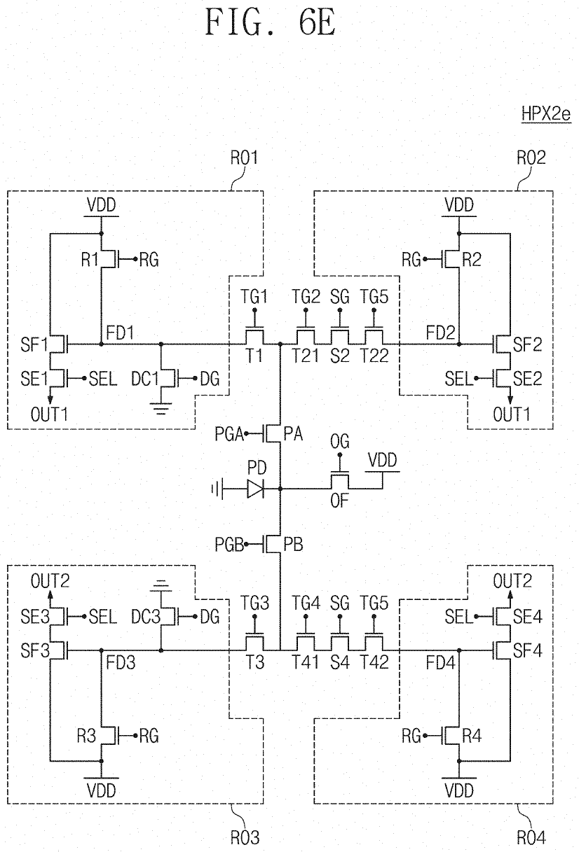

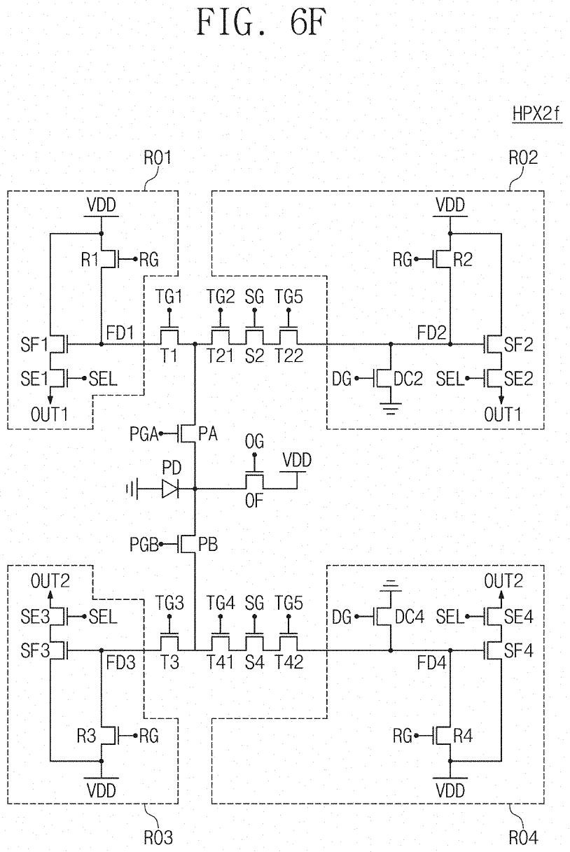

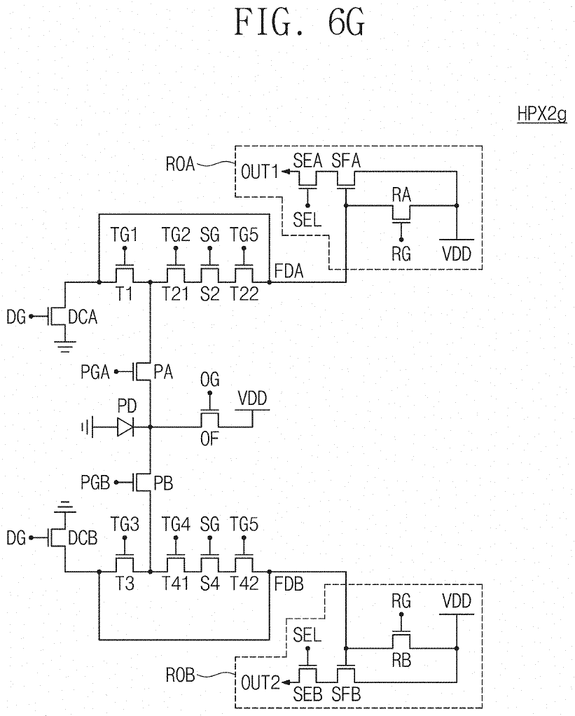

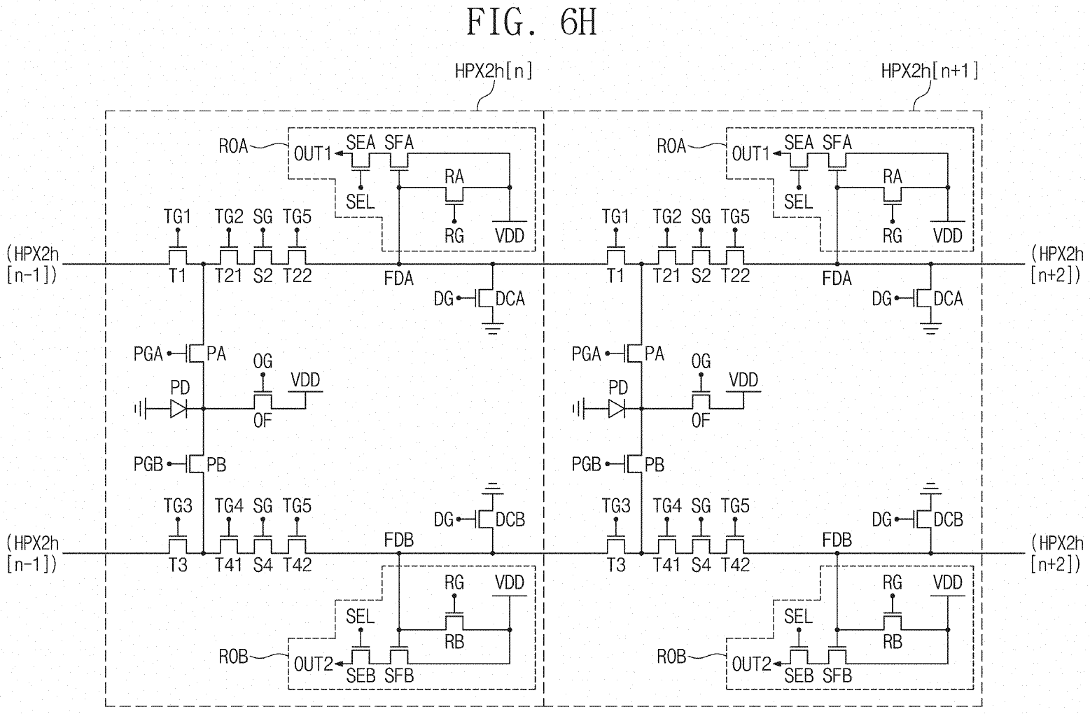

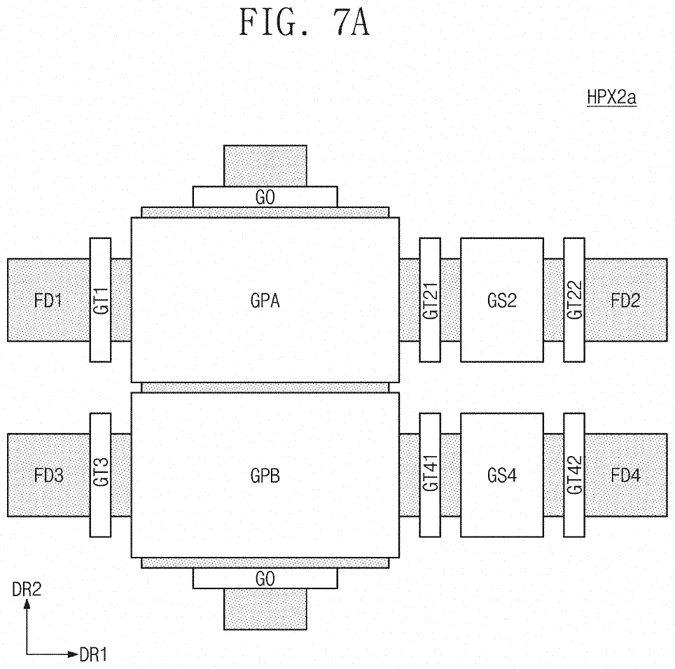

FIG. 6A illustrates a circuit diagram of a pixel of FIG. 1. A description will be focused on a difference between a pixel HPX2a and the pixel HPX1g. The pixel HPX2a may include the taps TAP1 to TAP4. The pixel HPX2a may include the photoelectric conversion element PD, photo transistors PA and PB, and the overflow transistor OF. The photoelectric conversion element PD, the photo transistors PA and PB, and the overflow transistor OF may be implemented substantially the same as the photoelectric conversion element PD, the photo transistors P1 and P2, and the overflow transistor “OF” of the pixel HPX1g and may operate substantially the same as those of the pixel HPX1g.

The tap TAP1 of the pixel HPX2a may correspond to the tap TAP1 of the pixel HPX1g. The tap TAP2 of the pixel HPX2a may correspond to the tap TAP2 of the pixel HPX1g. The photo transistor PA of the pixel HPX2a may be shared by the taps TAP1 and TAP2 of the pixel HPX2a. The tap TAP3 of the pixel HPX2a may correspond to the tap TAP1 of the pixel HPX1g. The tap TAP4 of the pixel HPX2a may correspond to the tap TAP2 of the pixel HPX1g. The photo transistor PB of the pixel HPX2a may be shared by the taps TAP3 and TAP4 of the pixel HPX2a.

During the integration period, one of the transfer transistors T1 and T21 may be selected by the transfer gate signals TG1 and TG2, and the other thereof may not be selected thereby. When the transfer transistor T1 is selected, an operation of the tap TAP1 in the pixel HPX2a may be substantially the same as that of the tap TAP1 in the pixel HPX1g, and charges integrated by the photo transistor PA may not be transferred to the storage transistor S2 and the floating diffusion area FD2. When the transfer transistor T21 is selected, an operation of the tap TAP2 in the pixel HPX2a may be substantially the same as that of the tap TAP2 in the pixel HPX1g, and the charges integrated by the photo transistor PA may not be transferred to the floating diffusion area FD1.

During the integration period, one, e.g. only one, of the transfer transistors T3 and T41 may be selected by the transfer gate signals TG3 and TG4, and the other thereof may not be selected thereby. When the transfer transistor T3 is selected, an operation of the tap TAP3 in the pixel HPX2a may be substantially the same as that of the tap TAP1 in the pixel HPX1g, and charges integrated by the photo transistor PB may not be transferred to the storage transistor S4 and the floating diffusion area FD4. When the transfer transistor T41 is selected, an operation of the tap TAP4 in the pixel HPX2a may be substantially the same as that of the tap TAP2 in the pixel HPX1g, and the charges integrated by the photo transistor PB may not be transferred to the floating diffusion area FD3.

In the high-illuminance condition, operating the tap TAP1 instead of the tap TAP2 may be advantageous, and the transfer transistors T1 and T3 may be selected during the integration period. In the low-illuminance condition, operating the tap TAP2 instead of the tap TAP1 may be advantageous, and the transfer transistors T21 and T41 may be selected during the integration period. In an intermediate operation condition of the high-illuminance condition and the low-illuminance condition, the transfer transistors T1 and T41 may be selected during the integration period, the transfer transistors T21 and T3 may be selected during the integration period, or all the transfer transistors T1, T21, T3, and T41 may be selected during the integration period. Dotted lines defining the taps TAP1 to TAP4 are not illustrated in FIGS. 6B to 6H for convenience of illustration.

FIG. 6B illustrates a circuit diagram of a pixel of FIG. 1. A description will be focused on a difference between a pixel HPX2b and the pixel HPX2a. The tap TAP3 of the pixel HPX2b may be disposed at a location of the tap TAP4 of the pixel HPX2a. The tap TAP4 of the pixel HPX2b may be disposed at a location of the tap TAP3 of the pixel HPX2a.

FIG. 6C illustrates a circuit diagram of a pixel of FIG. 1. A description will be focused on a difference between a pixel HPX2c and the pixel HPX2a. In the pixel HPX2c, the floating diffusion areas FD1 and FD2 of the pixel HPX2a may be electrically connected as a floating diffusion area FDA. The pixel HPX2c may include a readout circuit ROA connected to the floating diffusion area FDA. The readout circuit ROA may include a reset transistor RA, a source follower transistor SFA, and a selection transistor SEA. The floating diffusion area FDA and the readout circuit ROA may be shared by the taps TAP1 and TAP2 of an intra-pixel. In the pixel HPX2c, the floating diffusion areas FD3 and FD4 of the pixel HPX2a may be electrically connected as a floating diffusion area FDB. The pixel HPX2c may include a readout circuit ROB connected to the floating diffusion area FDB. The readout circuit ROB may include a reset transistor RB, a source follower transistor SFB, and a selection transistor SEB. The floating diffusion area FDB and the readout circuit ROB may be shared by the taps TAP3 and TAP4 of the intra-pixel.

FIG. 6D illustrates a circuit diagram of pixels of FIG. 1. A description will be focused on a difference between pixels HPX2d[n] and HPX2d[n+1] and the pixels HPX2a and HPX2c. Here, “n” may indicate a number, e.g. an integer number, of the pixel HPX2d, and the pixel HPX2d[n] and the pixel HPX2d[n+1] may be adjacent to each other along the row direction. The floating diffusion area FDA[n] of the tap TAP2 of the pixel HPX2d[n] and the floating diffusion area FDA[n] of the tap TAP1 of the pixel HPX2d[n+1] may be electrically connected. The pixel HPX2d[n] may include the readout circuit ROA connected to the floating diffusion area FDA[n]. The floating diffusion area FDA[n] and the readout circuit ROA may be shared by an inter-pixel (i.e., the pixels HPX2d[n] and HPX2d[n+1]) and by the tap TAP2 of the pixel HPX2d[n] and the tap TAP1 of the pixel HPX2d[n+1]. The floating diffusion area FDB[n] of the tap TAP4 of the pixel HPX2d[n] and the floating diffusion area FDB[n] of the tap TAP3 of the pixel HPX2d[n+1] may be electrically connected. The pixels HPX2d[n] may include the readout circuit ROB connected to the floating diffusion area FDB[n]. The floating diffusion area FDB[n] and the readout circuit ROB may be shared by the inter-pixel (i.e., the pixels HPX2d[n] and HPX2d[n+1]) and by the tap TAP4 of the pixel HPX2d[n] and the tap TAP3 of the pixel HPX2d[n+1].

The pixel HPX2d[n] and a pixel HPX2d[n−1] (not illustrated) may be adjacent to each other along the row direction. The tap TAP1 of the pixel HPX2d[n] and the tap TAP2 of the pixel HPX2d[n−1] may share a floating diffusion area and a readout circuit. The tap TAP3 of the pixel HPX2d[n] and the tap TAP4 of the pixel HPX2d[n−1] may share a floating diffusion area and a readout circuit. The pixel HPX2d[n+1] and a pixel HPX2d[n+2] (not illustrated) may be adjacent to each other along the row direction. The tap TAP2 of the pixel HPX2d[n+1] and the tap TAP1 of the pixel HPX2d[n+2] may share a floating diffusion area and a readout circuit. The tap TAP4 of the pixel HPX2d[n+1] and the tap TAP3 of the pixel HPX2d[n+2] may share a floating diffusion area and a readout circuit.

FIG. 6E illustrates a circuit diagram of a pixel of FIG. 1. A description will be focused on a difference between a pixel HPX2e and the pixels HPX2a, HPX1j, and HPX1k. The pixel HPX2e may further include a dual conversion transistor DC1 connected between the floating diffusion area FD1 and the power supply voltage GND and a dual conversion transistor DC3 connected between the floating diffusion area FD3 and the power supply voltage GND. Unlike FIG. 6E, the dual conversion transistor DC1 may be connected between the reset transistor R1 and the floating diffusion area FD1, and the dual conversion transistor DC3 may be connected between a reset transistor R3 and the floating diffusion area FD3 (refer to FIG. 3K).

FIG. 6F illustrates a circuit diagram of a pixel of FIG. 1. A description will be focused on a difference between a pixel HPX2f and the pixels HPX2a, HPX1l, and HPX1m. The pixel HPX2f may further include a dual conversion transistor DC2 connected between the floating diffusion area FD2 and the power supply voltage GND and a dual conversion transistor DC4 connected between the floating diffusion area FD4 and the power supply voltage GND. Unlike FIG. 6F, the dual conversion transistor DC2 may be connected between the reset transistor R2 and the floating diffusion area FD2, and the dual conversion transistor DC4 may be connected between, e.g. directly connected or connected without any additional active components such as transistors between the dual conversion transistor DC4, a reset transistor R4, and the floating diffusion area FD4 (refer to FIG. 3M).

FIG. 6G illustrates a circuit diagram of a pixel of FIG. 1. A description will be focused on a difference between a pixel HPX2g and the pixels HPX2c and HPX1n. The pixel HPX2g may further include a dual conversion transistor DCA connected between the floating diffusion area FDA and the power supply voltage GND and a dual conversion transistor DCB connected between, e.g. directly connected or connected without any additional active components between the dual conversion transistor DCB, the floating diffusion area FDB, and the power supply voltage GND. Unlike FIG. 6G, the dual conversion transistor DCA may be connected between the reset transistor RA and the floating diffusion area FDA, and the dual conversion transistor DCB may be connected between the reset transistor RB and the floating diffusion area FDB.

FIG. 6H illustrates a circuit diagram of a pixel of FIG. 1. A description will be focused on a difference between pixels HPX2h[n] and HPX2h[n+1] and the pixels HPX2d[n], HPX2d[n+1], HPX1o[n], and HPX1o[n+1]. The pixel HPX2h[n] may further include the dual conversion transistor DCA connected between, e.g. directly connected or connected without any additional active components between the dual conversion transistor DCA, the floating diffusion area FDA and the power supply voltage GND and the dual conversion transistor DCB connected between the floating diffusion area FDB and the power supply voltage GND. The pixel HPX2h[n+1] may further include the dual conversion transistor DCA connected between, e.g. directly connected or connected without any additional active components between the dual conversion transistor DCA, the floating diffusion area FDA, and the power supply voltage GND and the dual conversion transistor DCB connected between the floating diffusion area FDB and the power supply voltage GND. Unlike FIG. 6H, the dual conversion transistor DCA may be connected between, e.g. directly connected or connected without any additional active components between the dual conversion transistor DCA the reset transistor RA and the floating diffusion area FDA, and the dual conversion transistor DCB may be similarly connected between the reset transistor RB and the floating diffusion area FDB.

FIG. 7A illustrates a layout of a pixel of FIG. 6A. Readout circuits RO1 to RO4 of the pixel HPX2a are not illustrated in FIG. 7A. Gate electrodes GPA and GPB of the photo transistors PA and PB may be disposed adjacent to each other along the direction DR2. The gate electrode GO of the overflow transistor OF may be disposed adjacent to the gate electrode GPA or the gate electrode GPB along the direction DR2. The gate electrode GT1 of the transfer transistor T1 may be disposed adjacent to the gate electrode GPA along the direction DR1. The floating diffusion area FD1 may be disposed adjacent to the gate electrode GT1 along the direction DR1. The gate electrode GT21 of the transfer transistor T21 may be disposed adjacent to the gate electrode GPA along the direction DR1. The gate electrode GS2 of the storage transistor S2 may be disposed adjacent to the gate electrode GT21 along the direction DR1. The gate electrode GT22 of the transfer transistor T22 may be disposed adjacent to the gate electrode GS2 along the direction DR1. The floating diffusion area FD2 may be disposed adjacent to the gate electrode GT22 along the direction DR1.

The gate electrode GT3 of the transfer transistor T3 may be disposed adjacent to the gate electrode GPB along the direction DR1. The floating diffusion area FD3 may be disposed adjacent to the gate electrode GT3 along the direction DR1. The gate electrode GT41 of the transfer transistor T41 may be disposed adjacent to the gate electrode GPB along the direction DR1. The gate electrode GS4 of the storage transistor S4 may be disposed adjacent to the gate electrode GT41 along the direction DR1. The gate electrode GT42 of the transfer transistor T42 may be disposed adjacent to the gate electrode GS4 along the direction DR1. The floating diffusion area FD4 may be disposed adjacent to the gate electrode GT42 along the direction DR1.

Although not illustrated in FIG. 7A, the photoelectric conversion area PD may be disposed or formed in the substrate so as to overlap the gate electrodes GPA and GPB in a plan view. Storage diodes (refer to FIG. 3D) may be disposed or formed in the substrate so as to overlap the gate electrodes GS2 and GS4 in a plan view.

FIG. 7B illustrates a layout of a pixel of FIG. 6B. The readout circuits RO1 to RO4 of the pixel HPX2b are not illustrated in FIG. 7B. A description will be focused on a difference between a layout of the pixel HPX2b and the layout of the pixel HPX2a. The pixel HPX2a may be symmetrical with respect to a first axis. The transistors GT1, GPA, GT21, GS2, and GT22 and the transistors GT3, GPB, GT41, GS4, and GT42 may be symmetrical with respect to the first axis parallel to the direction DR1. The pixel HPX2a may be symmetrical with respect to an intersection of the first axis parallel to the direction DR1 and a second axis perpendicular to the first axis. The transistors GPA and GPB of the pixel HPX2b may be symmetrical with respect to the first axis. The transistors GT1, GT21, GT2, and GT22 may be symmetrical to the transistors GT3, GT41, GS4, and GT42 with respect to the intersection, respectively.

FIG. 7C illustrates a layout of a pixel of FIG. 6C. A description will be focused on a difference between a layout of the pixel HPX2c and the layout of the pixel HPX2a. A wire, e.g. a conductive wire integrated within the transistors, which electrically connects the floating diffusion area FDA of the tap TAP1 to the floating diffusion area FDA of the tap TAP2 may be provided on the pixel HPX2c or the pixel array 121. A wire, e.g. a conductive wire integrated within the transistors, which electrically connects the floating diffusion area FDB of the tap TAP3 to the floating diffusion area FDB of the tap TAP4 may be provided on the pixel HPX2c or the pixel array 121. The transistors RA, SFA, SEA, RB, SFB, and SEB corresponding to the read circuits ROA and ROB are illustrated as circuit-level transistors.

FIG. 7D illustrates a layout of a pixel of FIG. 6D. A description will be focused on a difference between a layout of the pixels HPX2d[n] and HPX2d[n+1] and the layout of the pixel HPX2a. The tap TAP2 of the pixel HPX2d[n] and the tap TAP1 of the pixel HPX2d[n+1] may share the floating diffusion area FDA. The tap TAP4 of the pixel HPX2d[n] and the tap TAP3 of the pixel HPX2d[n+1] may share the floating diffusion area FDB. The transistors RA, SFA, SEA, RB, SFB, and SEB corresponding to the read circuits ROA and ROB connected to the floating diffusion areas FDA and FDB are illustrated as circuit-level transistors.

FIG. 7E illustrates a layout of a pixel of FIG. 6E. A description will be focused on a difference between a layout of the pixel HPX2e and the layout of the pixel HPX2a. A gate electrode GDC1 of the dual conversion transistor DC1 may be disposed adjacent to the floating diffusion area FD1 along the direction DR1. A gate electrode GDC3 of the dual conversion transistor DC3 may be disposed adjacent to the floating diffusion area FD3 along the direction DR1. FIG. 7F illustrates a layout of a pixel of FIG. 6F. A description will be focused on a difference between a layout of the pixel HPX2f and the layout of the pixel HPX2a. A gate electrode GDC2 of the dual conversion transistor DC2 may be disposed adjacent to the floating diffusion area FD2 along the direction DR1. A gate electrode GDC4 of the dual conversion transistor DC4 may be disposed adjacent to the floating diffusion area FD4 along the direction DR1. FIG. 7G illustrates a layout of a pixel of FIG. 6G. A description will be focused on a difference between a layout of the pixel HPX2g and the layout of the pixel HPX2c. A gate electrode GDCA of the dual conversion transistor DCA may be disposed adjacent to the floating diffusion area FDA along the direction DR1. A gate electrode GDCB of the dual conversion transistor DCB may be disposed adjacent to the floating diffusion area FDB along the direction DR1.

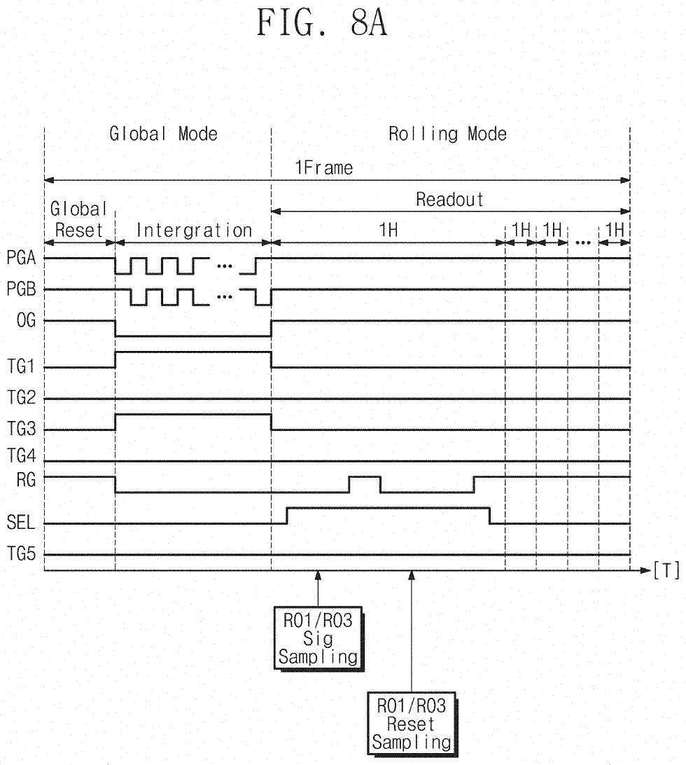

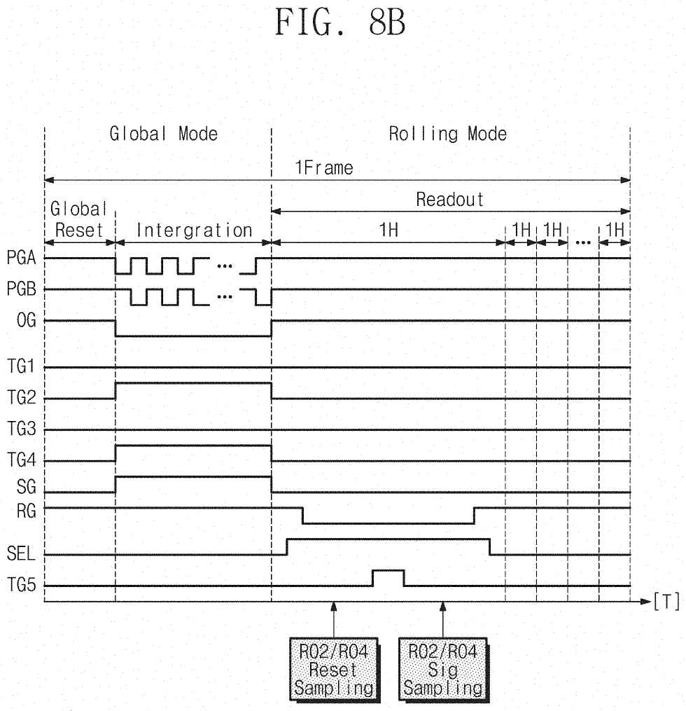

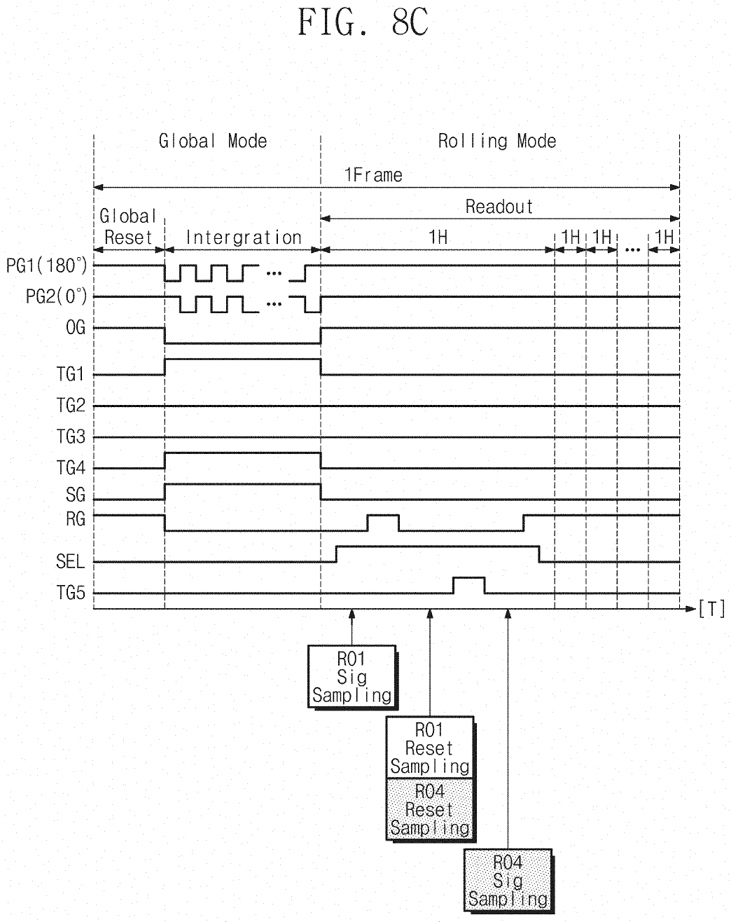

FIGS. 8A to 8C illustrate timing diagrams of signals that may be applied to a pixel of FIG. 6A. FIGS. 8A to 8C will be described with reference to the pixel HPX2a, but signals of FIGS. 8A to 8C may be applied to the above-described other pixels as well as the pixel HPX2a. A difference between the timing diagrams FIGS. 8A to 8C and the timing diagrams of FIGS. 5A and 5B will be described below.

Referring to FIG. 8A, the taps TAP1 and TAP3 of the pixel HPX2a may be selected. During the integration period, the transfer gate signals TG1 and TG3 may be activated, and the remaining transfer gate signals TG2 and TG4 may be deactivated. Afterwards, in the readout period of the rolling mode, the readout circuits RO1 and RO3 may respectively output the output signals OUT1 and OUT2 corresponding to signal levels of the floating diffusion areas FD1 and FD3, which are respectively determined by charges integrated by the respective photo transistors PA and PB (R01/R03 Sig Sampling). After the floating diffusion areas FD1 and FD3 are reset, the readout circuits RO1 and RO3 may respectively output the output signals OUT1 and OUT2 corresponding to reset levels of the floating diffusion areas FD1 and FD3 (R01/R03 Reset Sampling). In some example embodiments, unlike the example illustrated in FIG. 8A, the readout circuits RO1 and RO3 may respectively output the output signals OUT1 and OUT2 corresponding to the reset levels of the floating diffusion areas FD1 and FD3 that are reset during the global reset period before the integration period.

Referring to FIG. 8B, the taps TAP2 and TAP4 of the pixel HPX2a may be selected. During the integration period, the transfer gate signals TG2 and TG4 may be activated, and the remaining transfer gate signals TG1 and TG3 may be deactivated. After the integration period, the readout circuits RO2 and RO4 may respectively output the output signals OUT1 and OUT2 corresponding to reset levels of the floating diffusion areas FD2 and FD4 (RO2/R04 Reset Sampling). After the transfer transistors T22 and T44 are turned on and are turned off, the readout circuits RO2 and RO4 may respectively output the output signals OUT1 and OUT2 corresponding to signal levels of the floating diffusion areas FD2 and FD4, which are respectively determined by charges integrated by the respective photo transistors PA and PB (RO2/RO4 Sig Sampling).

Referring to FIG. 8C, the taps TAP1 and TAP4 of the pixel HPX2a may be selected. During the integration period, the transfer gate signals TG1 and TG4 may be activated, and the remaining transfer gate signals TG2 and TG3 may be deactivated. Unlike FIG. 8C, during the integration period, the transfer gate signals TG2 and TG3 may be activated, and the remaining transfer gate signals TG1 and TG4 may be deactivated. Afterwards, the readout circuit RO1 operates as described with reference to FIG. 8A, and the readout circuit RO4 operates as described with reference to FIG. 8B.

Each of the hybrid pixels HPX1a to HPX1r and HPX2a to HPX2h according to embodiments of inventive concepts may include both a tap having a relatively great FWC and a tap in which a reset noise or a read noise is relatively small. The hybrid pixel may select and operate a tap(s) appropriate for an operation condition (e.g., a low-illuminance condition or a high-illuminance condition) of the depth sensor 120. The components of the above-described pixels may be mutually combined. Reference symbols/numbers are repeatedly used in drawings to indicate components of the same or similar pixels.

A depth sensor according to some example embodiments of inventive concepts may select and operate an appropriate tap(s) of a hybrid pixel depending on an operation condition, such as a low-illuminance condition or a high-illuminance condition.

While inventive concepts has been described with reference to example embodiments thereof, it will be apparent to those of ordinary skill in the art that various changes and modifications may be made thereto without departing from the spirit and scope of inventive concepts as set forth in the following claims.

What is claimed is:

1. A depth sensor comprising a pixel, the pixel including:
a photo transistor;
a first transfer transistor connected to the photo transistor;
a first floating diffusion area connected to the first transfer transistor;
a second transfer transistor connected to the photo transistor;
a storage element connected to the second transfer transistor;
a third transfer transistor connected to the storage element; and
a second floating diffusion area connected to the third transfer transistor.

2. The depth sensor of claim 1, wherein, during an integration period where the photo transistor integrates charges, the depth sensor is configured to select one of the first and second transfer transistors, and the depth sensor is configured to not select the other of the first and second transistors.

3. The depth sensor of claim 1, wherein the pixel further includes:
a first readout circuit including a first reset transistor, a first source follower transistor, the first reset transistor and the first source follower transistor connected to the first floating diffusion area, and a first selection transistor connected to the first source follower transistor; and
a second readout circuit including a second reset transistor, a second source follower transistor, the second reset transistor and the second source follower transistor connected to the second floating diffusion area, and a second selection transistor connected to the second source follower transistor.

4. The depth sensor of claim 3, wherein, during an integration period where the photo transistor integrates charges, the depth sensor is configured to select the first transfer transistor, while the depth sensor is configured not to select the second transfer transistor, and
wherein the first readout circuit is configured to,
output a first output signal corresponding to a first voltage level of the first floating diffusion area after the integration period, and
output a second output signal corresponding to a second voltage level of the first floating diffusion area reset before the integration period or output a third output signal corresponding to a third voltage level of the first floating diffusion area reset after outputting the first output signal.

5. The depth sensor of claim 3, wherein, during an integration period where the photo transistor integrates charges, in response to the second transfer transistor being selected, while the first transfer transistor not being selected, the second readout circuit is configured to
output a first output signal corresponding to a first voltage level of the second floating diffusion area after the integration period, and
output a second output signal corresponding to a second voltage level of the second floating diffusion area after outputting the first output signal, such that the third transfer transistor is then turned on, and the third transfer transistor is then turned off.

6. The depth sensor of claim 1, wherein the first floating diffusion area and the second floating diffusion area are electrically connected.

7. The depth sensor of claim 6, wherein the pixel further includes:
a readout circuit including,
a reset transistor,
a source follower transistor connected to the first and second floating diffusion areas, and
a selection transistor connected to the source follower transistor.

8. The depth sensor of claim 1, wherein the pixel includes a first pixel, the photo transistor includes a first photo transistor, and the storage element includes a first storage element, and
wherein the depth sensor further includes a second pixel adjacent to the first pixel, the second pixel including,
a second photo transistor,
a fourth transfer transistor connected to the second photo transistor,
a third floating diffusion area connected to the fourth transfer transistor,
a fifth transfer transistor connected to the second photo transistor,
a second storage element connected to the fifth transfer transistor,
a sixth transfer transistor connected to the second storage element, and
a fourth floating diffusion area connected to the sixth transfer transistor, and
wherein the second floating diffusion area of the first pixel and the third floating diffusion area of the second pixel are electrically connected.

9. The depth sensor of claim 8, further comprising:
a readout circuit including,
a reset transistor,
a source follower transistor, the reset transistor and the source follower transistor connected to the second and third floating diffusion areas of the first and second pixels, and
a selection transistor connected to the source follower transistor.

10. The depth sensor of claim 1, wherein the pixel further includes:
a dual conversion transistor connected to the first floating diffusion area and configured to adjust a capacitance of the first floating diffusion area.

11. A depth sensor comprising a pixel, the pixel including:
a first photo transistor;
a first transfer transistor connected to the first photo transistor;
a first floating diffusion area connected to the first transfer transistor;
a second transfer transistor connected to the first photo transistor;
a first storage element connected to the second transfer transistor;
a third transfer transistor connected to the first storage element;
a second floating diffusion area connected to the third transfer transistor;
a second photo transistor;
a fourth transfer transistor connected to the second photo transistor;
a third floating diffusion area connected to the fourth transfer transistor;
a fifth transfer transistor connected to the second photo transistor;
a second storage element connected to the fifth transfer transistor;
a sixth transfer transistor connected to the second storage element; and
a fourth floating diffusion area connected to the sixth transfer transistor.

12. The depth sensor of claim 11, wherein, in a plan view of a layout of the depth sensor, the first photo transistor and the second photo transistor are symmetrical with respect to a first axis,
wherein the first transfer transistor and the fourth transfer transistor are symmetrical with respect to the first axis,
wherein the second transfer transistor and the fifth transfer transistor are symmetrical with respect to the first axis,
wherein the first storage element and the second storage element are symmetrical with respect to the first axis, and
wherein the third transfer transistor and the sixth transfer transistor are symmetrical with respect to the first axis.

13. The depth sensor of claim 11, wherein, in a plan view of a layout of the depth sensor, the first photo transistor and the second photo transistor are symmetrical with respect to a first axis,
wherein the first transfer transistor and the fourth transfer transistor are symmetrical with respect to an intersection of the first axis and a second axis perpendicular to the first axis,
wherein the second transfer transistor and the fifth transfer transistor are symmetrical with respect to the intersection,
wherein the first storage element and the second storage element are symmetrical with respect to the intersection, and
wherein the third transfer transistor and the sixth transfer transistor are symmetrical with respect to the intersection.

14. A depth sensor comprising a pixel, the pixel including:
a first photo transistor;
a first transfer transistor connected to the first photo transistor;
a first floating diffusion area connected to the first transfer transistor;
a second photo transistor;
a second transfer transistor connected to the second photo transistor;
a first storage element connected to the second transfer transistor;
a third transfer transistor connected to the first storage element; and
a second floating diffusion area connected to the third transfer transistor.

15. The depth sensor of claim 14, wherein the first photo transistor is configured to integrate charges based on a first modulation signal during a first integration period and to integrate charges based on a second modulation signal during a second integration period, the second modulation signal having a phase different from a phase of the first modulation signal, the second integration period being after the first integration period, and
wherein the second photo transistor is configured to integrate charges based on the second modulation signal during the first integration period and to integrate charges based on the first modulation signal during the second integration period.

16. The depth sensor of claim 14, wherein the pixel further includes:
a first readout circuit including a first reset transistor, a first source follower transistor, the first reset transistor and the first source follower transistor connected to the first floating diffusion area, and a first selection transistor connected to the first source follower transistor; and
a second readout circuit including a second reset transistor, a second source follower transistor, the second reset transistor and the second source follower transistor connected to the second floating diffusion area, and a second selection transistor connected to the second source follower transistor.

17. The depth sensor of claim 14, wherein the first floating diffusion area and the second floating diffusion area are electrically connected.

18. The depth sensor of claim 17, wherein the pixel further includes:
a readout circuit including a reset transistor, a source follower transistor, the reset transistor and the source follower transistor connected to the first and second floating diffusion areas, and a selection transistor connected to the source follower transistor.

19. The depth sensor of claim 14, wherein the depth sensor further comprises a second pixel adjacent to a first pixel being the pixel,
wherein the second pixel includes,
a third photo transistor,
a fourth transfer transistor connected to the third photo transistor,
a third floating diffusion area connected to the fourth transfer transistor,
a fourth photo transistor,
a fifth transfer transistor connected to the fourth photo transistor,
a second storage element connected to the fifth transfer transistor,
a sixth transfer transistor connected to the second storage element, and
a fourth floating diffusion area connected to the sixth transfer transistor, and
wherein the second floating diffusion area of the first pixel and the third floating diffusion area of the second pixel are electrically connected.

20. The depth sensor of claim 19, further comprising:
a readout circuit including a reset transistor, a source follower transistor, the reset transistor and the source follower transistor connected to the second and third floating diffusion areas of the first and second pixels, and a selection transistor connected to the source follower transistor.
